(19) United States
(12) Patent Application Publication
(10) Pub. No.: US 2026/0190571 A1
(43) Pub. Date: Jul. 2, 2026

(54) DISPLAY PANEL AND DISPLAY APPARATUS

(71) Applicant: Tianma Advanced Display Technology Institute (Xiamen) Co.,Ltd., Xiamen (CN)

(72) Inventors: Zhenyu JIA, Xiamen (CN); Linrong WU, Xiamen (CN); Kerui XI, Xiamen (CN); Canyuan ZHANG, Xiamen (CN); Yingteng ZHAI, Xiamen (CN)

(21) Appl. No.: 19/169,798

(22) Filed: Apr. 3, 2025

(30) Foreign Application Priority Data
Dec. 31, 2024 (CN) 202411996394.0

(51) Int. Cl. H10H 29/49; G09G 3/32

(52) U.S. Cl. CPC H10H 29/49; G09G 3/32; G09G 2300/0426; G09G 2300/0852; G09G 2310/0286

(57) ABSTRACT

The present disclosure provides a display panel and display apparatus. The display panel includes a display region, where the display region includes a plurality of light-emitting elements, a plurality of pixel circuits and at least one driving circuit; and the at least one driving circuit includes multi-level-cascaded shift register circuits; and an array substrate, where the array substrate includes the plurality of pixel circuits and the at least one driving circuit. The display region includes a plurality of sub-display regions; a sub-display region includes at least two alignment marks; an alignment mark is configured for alignment when a light-emitting element is transferred to the array substrate; the alignment mark is in a metal layer of the plurality of metal layers; a clearance region is configured around the alignment mark; and the plurality of metal layers exposes the alignment mark and the clearance region around the alignment mark.

### CROSS-REFERENCE TO RELATED APPLICATION

The present disclosure claims the priority of Chinese Patent Application No. 202411996394.0, filed on Dec. 31, 2024, the content of which is incorporated herein by reference in its entirety.

### TECHNICAL FIELD

The present disclosure generally relates to the field of display technology and, more particularly, relates to a display panel and a display apparatus.

### BACKGROUND

With the development of display technology, micro-LED display panels are increasingly used in display apparatuses such as smartphones, tablets, and laptops due to various advantages including excellent brightness, lifespan, contrast, response time, energy consumption, viewing angle, resolution and the like.

When transferring micro-LEDs to display regions of the array substrate through mass transfer technology, alignment marks may be required for alignment. In existing micro-LED display panels, alignment marks may be configured in non-display regions. With the development of display technology, display panels with extremely narrow borders or even without borders have gradually become mainstream, such that there is a need to configure alignment marks.

### SUMMARY

One aspect of the present disclosure provides a display panel. The display panel includes a display region, where the display region includes a plurality of light-emitting elements, a plurality of pixel circuits and at least one driving circuit; the at least one driving circuit includes multi-level-cascaded shift register circuits; the shift register circuits are configured to transmit a driving signal to the plurality of pixel circuits; and the plurality of pixel circuits is configured to drive the plurality of light-emitting elements; and an array substrate, where the array substrate includes the plurality of pixel circuits and the at least one driving circuit; and the plurality of light-emitting element is on the array substrate. The array substrate includes a base substrate, an active layer on a side of the base substrate, and a plurality of metal layers on a side of the active layer away from the base substrate; and the display region includes a plurality of sub-display regions; a sub-display region includes at least two alignment marks; an alignment mark is configured for alignment when a light-emitting element is transferred to the array substrate; the alignment mark is in a metal layer of the plurality of metal layers; a clearance region is configured around the alignment mark; and the plurality of metal layers exposes the alignment mark and the clearance region around the alignment mark.

Another aspect of the present disclosure provides a display apparatus including a display panel. The display panel includes a display region, where the display region includes a plurality of light-emitting elements, a plurality of pixel circuits and at least one driving circuit; the at least one driving circuit includes multi-level-cascaded shift register circuits; the shift register circuits are configured to transmit a driving signal to the plurality of pixel circuits; and the plurality of pixel circuits is configured to drive the plurality of light-emitting elements; and an array substrate, where the array substrate includes the plurality of pixel circuits and the at least one driving circuit; and the plurality of light-emitting element is on the array substrate. The array substrate includes a base substrate, an active layer on a side of the base substrate, and a plurality of metal layers on a side of the active layer away from the base substrate; and the display region includes a plurality of sub-display regions; a sub-display region includes at least two alignment marks; an alignment mark is configured for alignment when a light-emitting element is transferred to the array substrate; the alignment mark is in a metal layer of the plurality of metal layers; a clearance region is configured around the alignment mark; and the plurality of metal layers exposes the alignment mark and the clearance region around the alignment mark.

Other aspects of the present disclosure may be understood by those skilled in the art in light of the description, the claims, and the drawings of the present disclosure.

### BRIEF DESCRIPTION OF THE DRAWINGS

In order to clearly explain embodiments of the present disclosure or technical solutions in the existing technology, accompanying drawings required for describing embodiments or the existing technology are described hereinafter. Obviously, accompanying drawings in the present disclosure are merely used to describe embodiments of the present disclosure. Other drawings may also be obtained by those skilled in the art without any creative work according to accompanying drawings.

FIG. 1 illustrates a top view of a display panel according to various embodiments of the present disclosure.

FIG. 2 illustrates a circuit structural diagram of a pixel circuit according to various embodiments of the present disclosure.

FIG. 3 illustrates an electrical connection relationship schematic of a pixel circuit and a driving circuit in a display region of a display panel according to various embodiments of the present disclosure.

FIG. 4 illustrates a partial top view of a display panel according to various embodiments of the present disclosure.

FIG. 5 illustrates another top view of a display panel according to various embodiments of the present disclosure.

FIG. 6 illustrates a partial cross-sectional view of a display panel according to various embodiments of the present disclosure.

FIG. 7 illustrates another top view of a display panel according to various embodiments of the present disclosure.

FIG. 8 illustrates a partial cross-sectional view of an array substrate in a display panel according to various embodiments of the present disclosure.

FIG. 9 illustrates a partial layout structural schematic of an A1 region in a middle display region of a display panel shown in FIG. 7.

FIG. 10 illustrates a layout structural schematic of an active layer q in FIG. 9.

FIG. 11 illustrates a layout structural schematic of a first metal layer M3 in FIG. 9.

FIG. 12 illustrates a layout structural schematic of a second metal layer M4 in FIG. 9.

FIG. 13 illustrates a layout structural schematic of a stacked layer of a first metal layer M3 and a second metal layer M4 in FIG. 9.

FIG. 14 illustrates another partial cross-sectional view of an array substrate in a display panel according to various embodiments of the present disclosure.

FIG. 15 illustrates another partial layout structural schematic of an A1 region in a middle display region of a display panel shown in FIG. 7.

FIG. 16 illustrates a layout structural schematic of an active layer q in FIG. 15.

FIG. 17 illustrates a layout structural schematic of a first metal layer M3 in FIG. 15.

FIG. 18 illustrates another layout structural schematic of a second metal layer M4 in FIG. 15.

FIG. 19 illustrates a layout structural schematic of a first metal layer M3 in an A2 region of a display region adjacent to an edge of a display panel shown in FIG. 7.

FIG. 20 illustrates a layout structural schematic of a second metal layer M4 in an A2 region of a display region adjacent to an edge of a display panel shown in FIG. 7.

FIG. 21 illustrates a partial enlarged schematic of a first metal layer M3 and a second metal layer M4 in a wiring region FF.

FIG. 22 illustrates a partial layout structural schematic of a second metal layer M4 at a wiring region in a display panel according to various embodiments of the present disclosure.

FIG. 23 illustrates a layout structural schematic of a stacked layer of a first metal layer M3 and a second metal layer M4 in FIG. 22.

FIG. 24 illustrates another layout structural schematic of a stacked layer of a first metal layer M3 and a second metal layer M4 in FIG. 22.

FIG. 25 illustrates another partial enlarged schematic of a first metal layer M3 and a second metal layer M4 in a wiring region FF.

FIG. 26 illustrates another layout structural schematic of a stacked layer of a first metal layer M3 and a second metal layer M4 in FIG. 22.

FIG. 27 illustrates another partial layout structural schematic of a second metal layer M4 at a wiring region in a display panel according to various embodiments of the present disclosure.

FIG. 28 illustrates a layout structural schematic of a stacked layer of a first metal layer M3 and a second metal layer M4 in FIG. 27.

FIG. 29 illustrates another partial enlarged schematic of a first metal layer M3 and a second metal layer M4 in a wiring region FF.

FIG. 30 illustrates another partial enlarged schematic of a first metal layer M3 and a second metal layer M4 in a wiring region FF.

FIG. 31 illustrates a partial enlarged schematic of a third metal layer M2, a first metal layer M3 and a second metal layer M4 in a wiring region FF.

FIG. 32 illustrates another partial enlarged schematic of a third metal layer M2, a first metal layer M3 and a second metal layer M4 in a wiring region FF.

FIG. 33 illustrates another top view of a display panel according to various embodiments of the present disclosure.

FIG. 34 illustrates another top view of a display panel according to various embodiments of the present disclosure.

FIG. 35 illustrates a structural schematic of a display apparatus according to various embodiments of the present disclosure.

FIG. 36 illustrates another structural schematic of a display apparatus according to various embodiments of the present disclosure.

### DETAILED DESCRIPTION

The technical solutions in embodiments of the present disclosure are clearly described by combining accompanying drawings and embodiments of the present disclosure. Obviously, described embodiments may be only a part, not all, of embodiments of the present disclosure. Based on embodiments in the present disclosure, all other embodiments obtained by those skilled in the field without creative work may be within the scope of protection of the present disclosure.

The terms “first”, “second” and the like in the present disclosure, claims and above-mentioned drawings may be configured to distinguish similar objects and may be not necessarily configured to describe a specific order or sequence. It may be understood that the terms used in such way may be interchanged where appropriate, which may be merely a manner of distinguishing objects of same attributes when embodiments of the present disclosure are described. In addition, the terms “include”, “have” and any variations may be intended to cover non-exclusive inclusions, such that a process, a method, a system, a product or a device containing a series of units may be not necessarily limited to those units but may include other units that are not clearly listed or inherent to the process, the method, the product or the device.

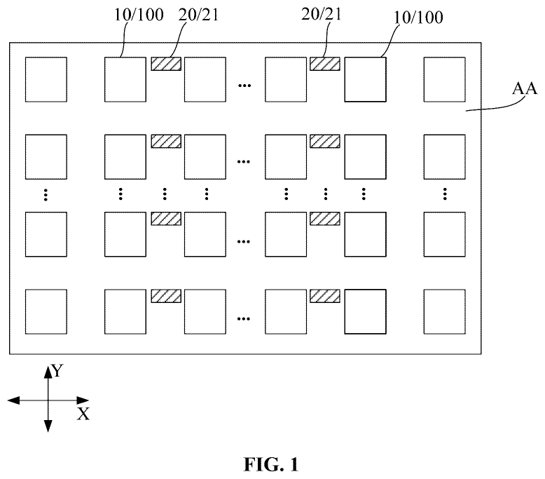

FIG. 1 illustrates a top view of a display panel according to various embodiments of the present disclosure. As shown in FIG. 1, the display panel may include a display region AA and may include a plurality of pixel circuits 10 and at least one driving circuit 20; the driving circuit 20 may include shift register circuits 21 configured in multi-level cascaded manner; and the shift register circuit 21 may be configured to transmit a driving signal to the pixel circuit 10.

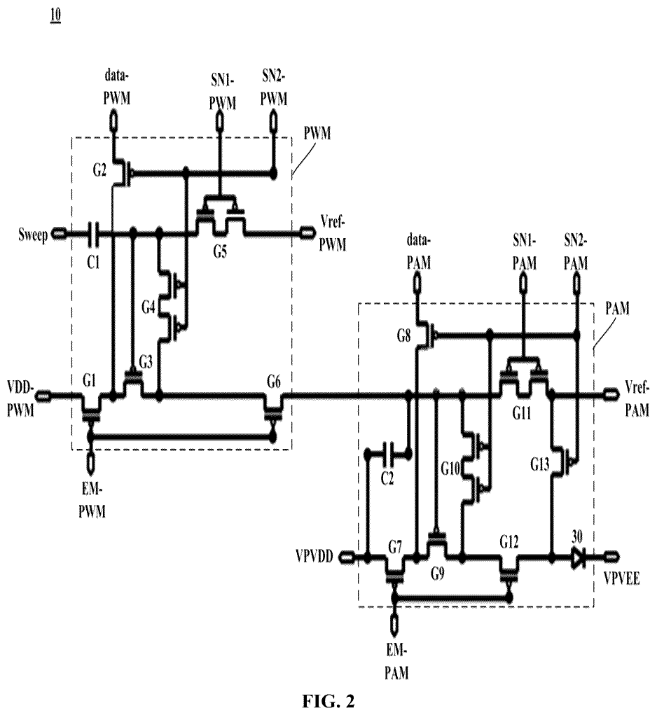

To understand the present disclosure, FIG. 2 illustrates a circuit structural diagram of the pixel circuit 10 according to various embodiments of the present disclosure. As shown in FIG. 2, the pixel circuit 10 may be a 13T2C structure. The pixel circuit 10 may include a pulse width module PWM controlled by pulse width modulation and an amplitude module PAM controlled by pulse amplitude modulation to achieve desirable performance of the light-emitting efficiency and viewing angle color deviation of the driven light-emitting element 30 (micro light-emitting diode). The pulse width module PWM in the pixel circuit 10 may include 6 thin-film transistors (G1-G6) and a capacitor (C1). The pulse width module PWM may receive a scan signal SN1-PWM, a scan signal SN2-PWM, a light-emitting control signal EM-PWM, a reference voltage signal Vref-PWM, a data signal data-PWM, a turnoff voltage signal VDD-PWM and a pulse width control voltage signal Sweep. The pulse width module PWM may be configured to control the light-emitting duration of the light-emitting element 30 (e.g., the light-emitting diode). The amplitude module PAM in the pixel circuit 10 may include 7 thin-film transistors (G7-G13) and a capacitor (C2). The amplitude module PAM may receive the scan signal SN1-PWM, the scan signal SN2-PWM, the light-emitting control signal EM-PWM, the reference voltage signal Vref-PWM, the data signal data-PWM and the first power supply voltage signal VPVDD. The amplitude module PAM may be electrically connected to one electrode of the light-emitting element 30, and another electrode of the light-emitting element 30 may be configured to receive the second power supply voltage signal VPVEE. The amplitude module PAM may be configured to control the light-emitting intensity of the light-emitting element 30 (e.g., the light-emitting diode). The electrical connection relationship between the transistors and the electrical connection relationship between the transistors and the signal lines in the 13T2C pixel circuit are shown in FIG. 2, which may not be described in detail herein.

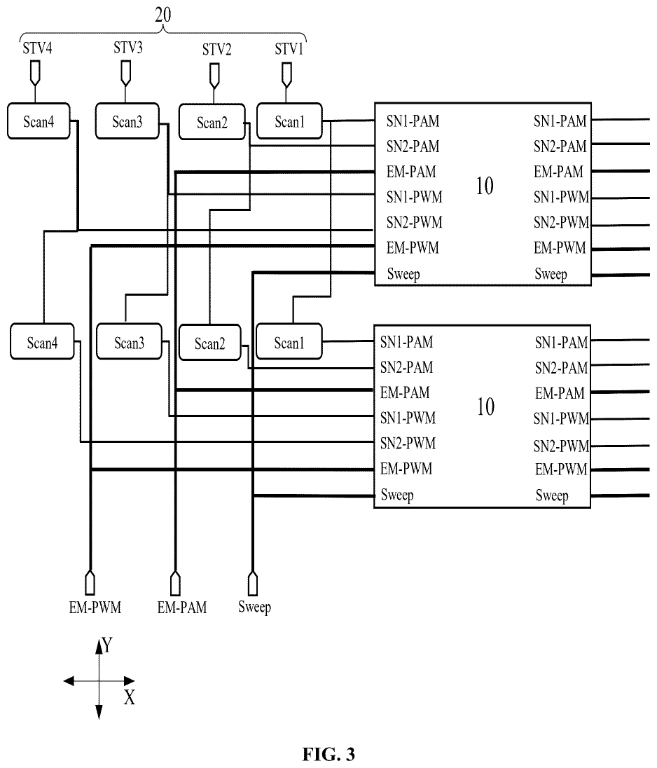

FIG. 3 illustrates an electrical connection relationship schematic of the pixel circuit 10 and the driving circuit 20 in the display region AA of the display panel according to various embodiments of the present disclosure. Referring to FIGS. 1-3, the driving circuit 20 may include a scan circuit STV1, a scan circuit STV2, a scan circuit STV3 and a scan circuit STV4. The scan circuit STV1 may include multi-level-cascaded shift register circuits Scan1 which may provide a scan signal SN1-PAM to the amplitude module PAM in the pixel circuit 10; the scan circuit STV2 may include multi-level-cascaded shift register circuits Scan2 which may provide a scan signal SN2-PAM to the amplitude module PAM in the pixel circuit 10; the scan circuit STV3 may include multi-level-cascaded shift register circuits Scan3 which may provide a scan signal SN1-PWM to the pulse width module PWM in the pixel circuit 10; and the scan circuit STV4 may include multi-level-cascaded shift register circuits Scan4 which may provide a scan signal line SN2-PWM to the amplitude module PWM in the pixel circuit 10. In addition, FIG. 3 also illustrates that the amplitude module PWM in the pixel circuit 10 may also receive the light-emitting control signal EM-PWM and the pulse width control voltage signal Sweep, and the amplitude module PAM in the pixel circuit 10 may also receive the light-emitting control signal EM-PAM.

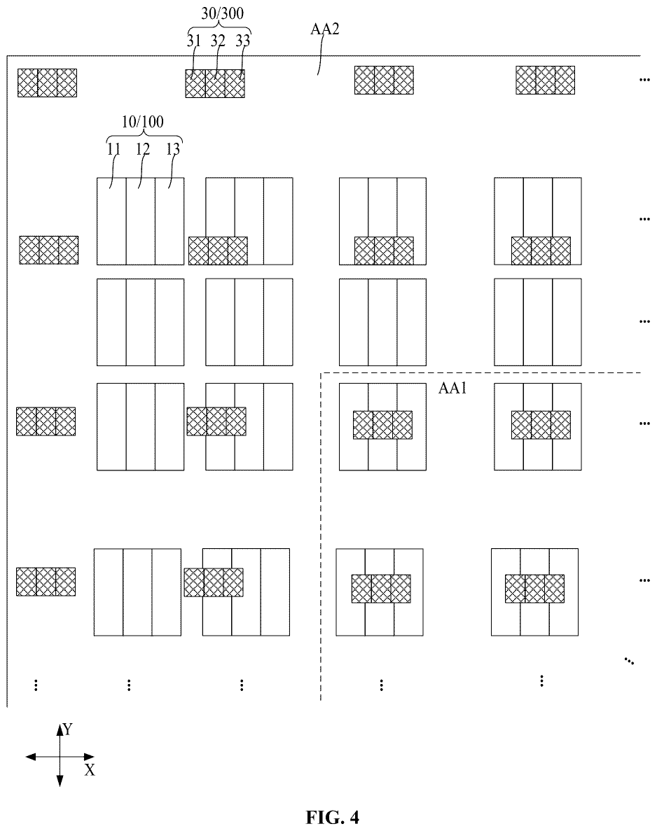

FIG. 4 illustrates a partial top view of a display panel according to various embodiments of the present disclosure. As shown in FIG. 4, the display panel may include a plurality of light-emitting elements 30; and referring to FIG. 2, the pixel circuit 10 may be electrically connected to the light-emitting element 30 and configured to drive the light-emitting element 30 to emit light. The light-emitting element 30 may be a micro light-emitting diode such as a sub-millimeter light-emitting diode (Mini-LED) or a micro light-emitting diode (Micro-LED).

As shown in FIG. 4, the display panel may include a pixel circuit group 100; the pixel circuit group 100 may include at least two pixel circuits 10; the pixel circuit groups 100 may be arranged in a row along the first direction X; multiple rows of pixel circuit groups 100 may be arranged along the second direction Y; the first direction X may intersect the second direction Y; and the first direction X and the second direction Y may be in parallel with the plane where the display panel is located. Correspondingly, as shown in FIG. 4, the display panel may also include a light-emitting element group 300; the light-emitting element group 300 may include at least two light-emitting elements 30; the light-emitting element groups 300 may be also arranged in a row along the first direction X; and multiple rows of light-emitting element groups 300 may be also arranged along the second direction Y. The pixel circuit group 100 and the light-emitting element group 300 may be electrically connected to each other accordingly.

Optionally, as shown in FIG. 4, the light-emitting elements 30 may include the first light-emitting element 31, the second light-emitting element 32 and the third light-emitting element 33. The first light-emitting element 31 may be configured to emit red light, the second light-emitting element 32 may be configured to emit green light, and the third light-emitting element 33 may be configured to emit blue light. One light-emitting element group 300 may include the first light-emitting element 31, the second light-emitting element 32 and the third light-emitting element 33. Correspondingly, as shown in FIG. 4, one pixel circuit group 100 may include the first pixel circuit 11 for driving the first light-emitting element 31 to emit light, the second pixel circuit 12 for driving the second light-emitting element 32 to emit light, and the third pixel circuit 13 for driving the third light-emitting element 33 to emit light.

In order to configure at least one driving circuit 20 in the display region AA, and also considering that the pixel circuit 10 needs to have a certain distance from the frame of the display panel, as shown in FIG. 4, in the edge region of the display region AA (e.g., the region AA2 in FIG. 4), the pixel circuit 10 and the light-emitting element 30 electrically connected to the pixel circuit 10 correspondingly may be at least not partially overlapped with each other along the direction perpendicular to the plane where the display panel is located, and in the middle region of the display region AA (e.g., the region AA1 in FIG. 4), the pixel circuit 10 and the light-emitting element 30 electrically connected to the pixel circuit 10 correspondingly may be at least partially overlapped with each other along the direction perpendicular to the plane where the display panel is located. In other words, in the edge region of the display region AA (e.g., the region AA2 in FIG. 4), the pixel circuit group 100 and the light-emitting element group 300 electrically connected to the pixel circuit group 100 correspondingly may be at least not partially overlapped with each other along the direction perpendicular to the plane where the display panel is located, and in the middle region of the display region AA (e.g., the region AA1 in FIG. 4), the pixel circuit group 100 and the connected light-emitting element group 300 electrically connected to the pixel circuit group 100 correspondingly may be at least partially overlapped with each other along the direction perpendicular to the plane where the display panel is located, such that the display panel with an extremely narrow frame or even no frame may be realized.

Optionally, as shown in FIG. 1, the shift register circuit 21 may be between different columns of pixel circuits 10; or in other words, the shift register circuit 21 may be between different columns of pixel circuit groups 100.

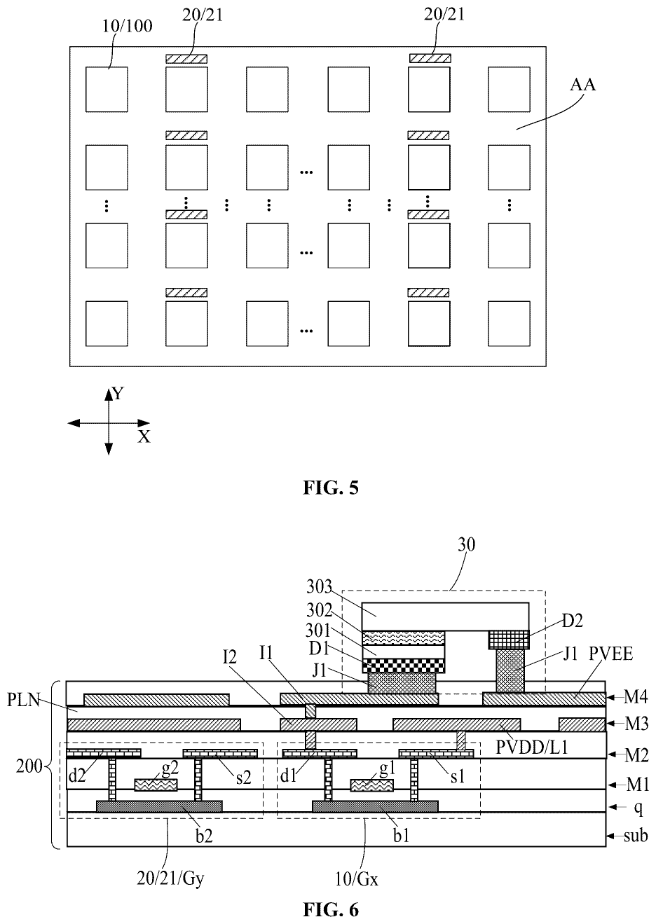

FIG. 5 illustrates another top view of a display panel according to various embodiments of the present disclosure. As shown in FIG. 5, optionally, the shift register circuit 21 may also be between different rows of pixel circuits 10; or in other words, the shift register circuit 21 may be between different rows of pixel circuit groups 100.

FIG. 6 illustrates a partial cross-sectional view of a display panel according to various embodiments of the present disclosure. As shown in FIG. 6, the display panel may include an array substrate 200; the array substrate 200 may include the pixel circuit 10 and the driving circuit 20; and the light-emitting element 30 may be on the array substrate 200, that is, the light-emitting element 30 may be transferred to the array substrate 200.

As shown in FIG. 6, the array substrate 200 may include a base substrate sub, an active layer q on the side of the base substrate sub, and a plurality of metal layers on the side of the active layer q away from the base substrate sub. The plurality of metal layers may include, for example, a metal layer M1, a metal layer M2, a metal layer M3, and a metal layer M4 which are arranged in sequence along the direction away from the base substrate sub.

As shown in FIG. 6, the light-emitting element 30 may include a first semiconductor layer 301, an active layer 302, and a second semiconductor layer 303 which are stacked with each other. The first semiconductor layer 301 may be electrically connected to the first electrode D1, and the second semiconductor layer 303 may be electrically connected to the second electrode D. The first electrode D1 and the second electrode D2 of the light-emitting element 30 may be bonded to the array substrate 200 through a bonding layer J1, and the light-emitting element 30 may be electrically connected to the pixel circuit 10.

As shown in FIG. 6, a thin-film transistor Gx in the pixel circuit 10 (e.g., any one of G1-G13 in FIG. 2) may include an active portion b1, a gate electrode g1, a source electrode s1 and a drain electrode d1; and the active portion b1 of the thin-film transistor Gx may be in the active layer q. Similarly, a thin-film transistor Gy in the driving circuit 20 may also include an active portion b2, a gate electrode g2, a source electrode s2 and a drain electrode d2; and the active portion b2 of the thin-film transistor Gy may be in the active layer q.

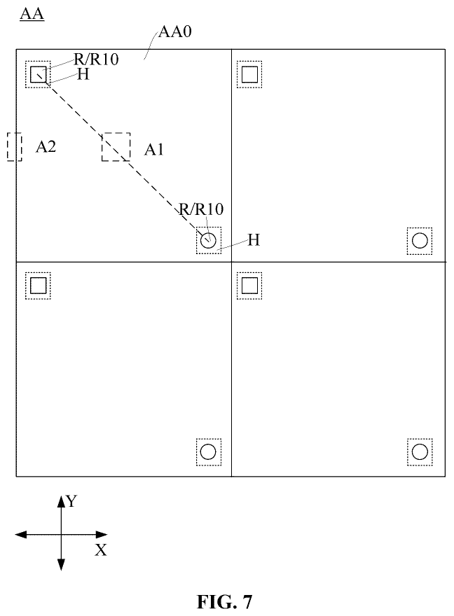

FIG. 7 illustrates another top view of a display panel according to various embodiments of the present disclosure. As shown in FIG. 7, the display region AA of the display panel may include a plurality of sub-display regions AA0, and the sub-display region AA0 may include at least two alignment marks R. The alignment marks R may be used for alignment when the light-emitting element 30 is transferred to the array substrate 200, and a clearance region H may be configured around the alignment marks R.

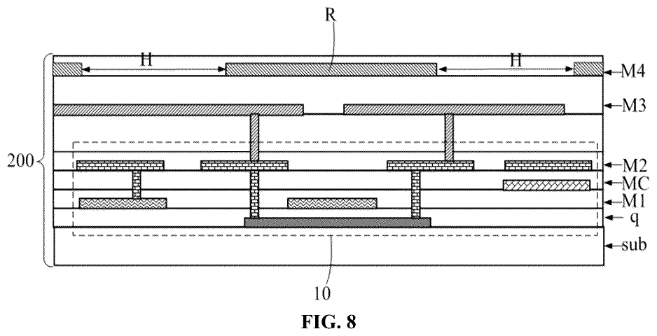

FIG. 8 illustrates a partial cross-sectional view of the array substrate 200 in the display panel according to various embodiments of the present disclosure. Referring to FIGS. 6-8, the alignment mark R may be in a metal layer of the plurality of metal layers on the side of the active layer q away from the base substrate sub; and the plurality of metal layers on the side of the active layer q away from the base substrate sub may expose the alignment mark R and the clearance region H around the alignment mark R. In the array substrate 200 shown in FIG. 8, the plurality of metal layers on the side of the active layer q away from the base substrate sub may also include a metal layer MC between the metal layer M1 and the metal layer M2.

It may be understood that when the light-emitting element 30 is transferred to the array substrate 200, the alignment mark R may need to be accurately identified. In order to accurately identify the alignment mark R, the clearance region H may need to be configured around the alignment mark R. Therefore, when the array substrate 200 is viewed from the bottom along the direction toward the base substrate sub, only the alignment mark R may be seen within the alignment mark R and the clearance region H around the alignment mark R, and no other shapes may be seen. It may also be understood that the plurality of metal layers on the side of the active layer q away from the base substrate sub may need to expose the alignment mark R and the clearance region H around the alignment mark R, such that the alignment mark R may be identified.

It may also be understood that the display region AA may be divided into the plurality of sub-display regions AA0, and each sub-display region AA0 may be configured with at least two alignment marks R. In such way, when the light-emitting element 30 is transferred to the array substrate 200, the accuracy of identifying the alignment mark R and the alignment accuracy of transferring the light-emitting element 30 to the array substrate 200 may be improved.

It may be seen that the display panel provided in embodiments of the present disclosure may be an extremely narrow frame or even a frameless display panel by setting at least one driving circuit 20 in the display region AA; and by dividing the display region AA into the plurality of sub-display regions AA0 and setting at least two alignment marks R in the sub-display region AA0, the alignment mark R in the sub-display region AA0 may be configured to align the light-emitting element 30 when the light-emitting element 30 is transferred to the array substrate 200 of the display panel. Meanwhile, the alignment mark R may be configured in a metal layer in the plurality of metal layers on the side of the active layer q away from the base substrate sub, and the clearance region H may be configured around the alignment mark R. The plurality of metal layers on the side of the active layer away from the base substrate sub may expose the alignment mark R and the clearance region H around the alignment mark R, which may ensure that the alignment mark R is accurately identified. Finally, the light-emitting element 30 may be accurately transferred to the array substrate 200 of the display panel.

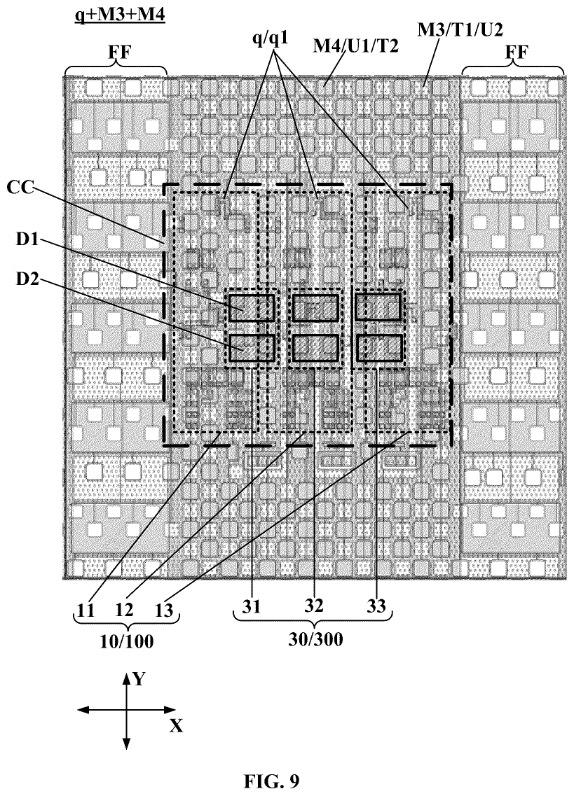

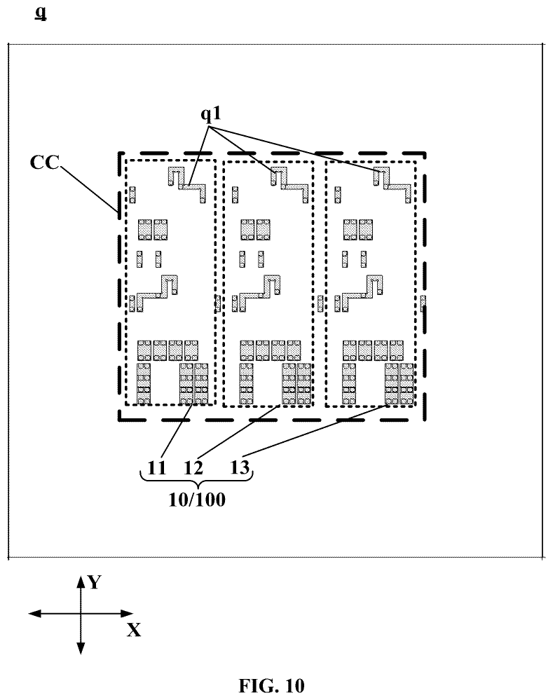

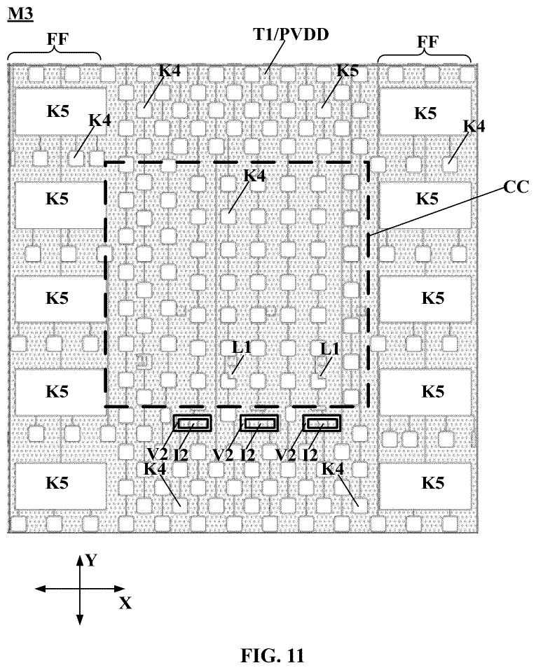

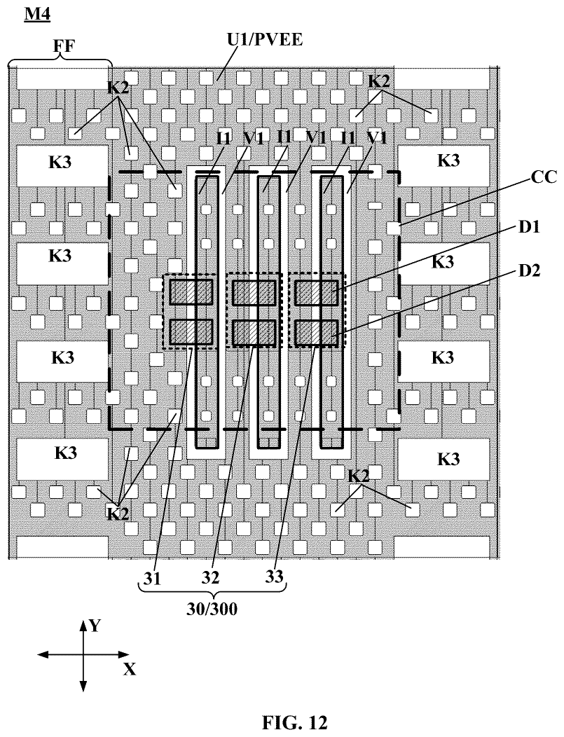

As disclosed above, the plurality of metal layers on the side of the active layer q away from the base substrate sub may include the first metal layer M3 and the second metal layer M4; and the second metal layer M4 may be on the side of the first metal layer M3 away from the base substrate sub. FIG. 9 illustrates a partial layout structural schematic of an A1 region in a middle display region of a display panel shown in FIG. 7. For the sake of clarity, FIG. 9 only shows the layout structure of the active layer q, the layout structure of the first metal layer M3, and the layout structure of the second metal layer M4. FIG. 10 further illustrates a layout structural schematic of the active layer q in FIG. 9. FIG. 11 further illustrates a layout structural schematic of the first metal layer M3 in FIG. 9. FIG. 12 further illustrates a layout structural schematic of the second metal layer M4 in FIG. 9.

As shown in FIGS. 9 and 11, the first metal layer M3 may include a physical part (e.g., solid section) T1 and a plurality of openings T2; the physical part T1 of the first metal layer M3 may include a first power supply structure PVDD; and the first power supply structure PVDD may be configured to provide the first power voltage signal VPVDD.

As shown in FIGS. 9 and 12, the second metal layer M4 may include the physical part U1 and the plurality of openings U2; the physical part U1 of the second metal layer M4 may include a second power supply structure PVEE; and the second power supply structure PVEE may be configured to provide the second power voltage signal VPVEE.

As shown in FIGS. 2 and 6, the first power supply structure PVDD may be electrically connected to the pixel circuit 10, the pixel circuit 10 may be electrically connected to the first electrode D1 of the light-emitting element 30, and the second power supply structure PVEE may be electrically connected to the second electrode D2 of the light-emitting element 30.

Corresponding to the layout structure, as shown in FIGS. 9-10, the active layer q of the display panel may include the first active portion q1, and the pixel circuit 10 may include the first active portion q1, and the first active portion q1 may include the active portion of each thin-film transistor in the pixel circuit 10. In the present disclosure. For the sake of clarity, the first active portion q1 in the pixel circuit 10 may represent the pixel circuit 10. It may be understood that the pixel circuit 10 may also include other film layer structures.

FIGS. 9 and 12 also illustrate the bonding position of the first electrode D1 and the second electrode D2 of the light-emitting element 30. For the convenience of notation, the bonding position of the first electrode D1 and the second electrode D2 of the light-emitting element 30 may represent the light-emitting element 30.

Referring to FIGS. 6 and 9-12, it may be seen that the second power supply structure PVEE may be electrically connected to the second electrode D2 of the light-emitting element 30.

Referring to FIGS. 6 and 9-12, it may be seen that the first power supply structure PVDD may include the first connection portion L1; and the first power supply structure PVDD may be electrically connected to the pixel circuit 10 through the first connection portion L1. Referring to FIGS. 6 and 9-12, it may also be seen that the physical part U1 of the second metal layer M4 may also include the first auxiliary electrode I1, and an opening V1 may be between the first auxiliary electrode I1 and the second power supply structure PVEE, such that the first auxiliary electrode I1 and the second power supply structure PVEE may be insulated from each other. Furthermore, the physical part T1 of the first metal layer M3 may also include the second auxiliary electrode I2, and an opening V2 may be between the second auxiliary electrode I2 and the first power supply structure PVDD, such that the second auxiliary electrode I2 and the first power supply structure PVDD may be insulated from each other. In such way, the pixel circuit 10 may be electrically connected through the second auxiliary electrode I2, the first auxiliary electrode I1 and the first electrode D1 of the light-emitting element 30 in sequence.

Optionally, in some embodiments of the present disclosure, the first power supply structure PVDD in the first metal layer M3 and the second power supply structure PVEE in the second metal layer M4 may be configured to be a grid design; the first metal layer M3 and the second metal layer M4 may have hollow regions; and the alignment mark R and the clearance region H around the alignment mark R may be configured in the hollow region of the second metal layer M4 or in the hollow region of the first metal layer M3.

However, when the first power supply structure PVDD in the first metal layer M3 and the second power supply structure PVEE in the second metal layer M4 is configured to be a grid design, due to process limitations, the thickness of the first metal layer M3 may be limited to a certain extent, such that the impedance of the first power supply structure PVDD may be relatively large, and the difference in IR drop across entire surface of the first power supply structure PVDD may be relatively large, which may easily affect the brightness uniformity of the display panel; similarly, the thickness of the second metal layer M4 may be also limited to a certain extent, such that the impedance of the second power supply structure PVEE may be relatively large, and the difference in IR drop across entire surface of the second power supply structure PVEE may be relatively large, which may easily affect the brightness uniformity of the display panel.

Therefore, if the area of the first power supply structure PVDD is increased, the impedance of the first power supply structure PVDD may be reduced, thereby improving the uniformity of the display brightness of the display panel. If the area of the second power supply structure PVEE is increased, the impedance of the second power supply structure PVEE may be reduced, thereby improving the uniformity of the display brightness of the display panel. If the area of the first power supply structure PVDD and the area of the second power supply structure PVEE are both increased, the impedance of the first power supply structure PVDD may be reduced, and the impedance of the second power supply structure PVEE may also be reduced, thereby improving the uniformity of the display brightness of the display panel.

As shown in FIGS. 9-12, the display panel may include the pixel circuit group 100; the pixel circuit group 100 may include at least two pixel circuits 10; the pixel circuit groups 100 may be arranged in a row along the first direction X; and multiple rows of pixel circuit groups 100 may be arranged along the second direction Y. Accordingly, the display panel may also include the light-emitting element group 300; the light-emitting element group 300 may include at least two light-emitting elements 30; the light-emitting element groups 300 may be also arranged in a row along the first direction X; multiple rows of light-emitting element groups 300 may be also arranged along the second direction Y; the pixel circuit group 100 and the light-emitting element group 300 may be electrically connected to each other accordingly.

Optionally, as shown in FIGS. 9-12, the light-emitting elements 30 may include the first light-emitting element 31, the second light-emitting element 32 and the third light-emitting element 33; the first light-emitting element 31 may be configured to emit red light, the second light-emitting element 32 may be configured to emit green light, and the third light-emitting element 33 may be configured to emit blue light; and one light-emitting element group 300 may include the first light-emitting element 31, the second light-emitting element 32 and the third light-emitting element 33. Correspondingly, as shown in FIGS. 9-12, one pixel circuit group 100 may include the first pixel circuit 11 for driving the first light-emitting element 31 to emit light, the second pixel circuit 12 for driving the second light-emitting element 32 to emit light, and the third pixel circuit 13 for driving the third light-emitting element 33 to emit light.

In order to increase the areas of the first power supply structure PVDD and the second power supply structure PVEE, optionally, as shown in FIGS. 9-12, along the direction perpendicular to the plane of the base substrate sub, the first power supply structure PVDD may be at least partially overlapped with one pixel circuit group 100, and the second power supply structure PVEE may be at least partially overlapped with one pixel circuit group 100. Furthermore, optionally, as shown in FIGS. 9-12, along the direction perpendicular to the plane of the base substrate sub, the orthographic projection region of the first power supply structure PVDD on the plane of the base substrate sub may cover the orthographic projection area of one pixel circuit group 100 on the plane of the base substrate sub; and the orthographic projection region of the second power supply structure PVEE on the plane of the base substrate sub may cover the orthographic projection area of one pixel circuit group 100 on the plane of the base substrate sub.

In actual process, arc discharge may easily occur when large-area metal is patterned in a vacuum machine, so that the area of the physical part T1 of the first metal layer M3 and the area of the physical part U1 of the second metal layer M4 may be limited. Furthermore, along the direction perpendicular to the plane of the base substrate sub, if the overlapping area of the physical part T1 of the first metal layer M3 and the physical part U1 of the second metal layer M4 is relatively large, it may easily cause short circuit between the first metal layer M3 and the second metal layer M4 when the insulating layer between above two metal layers is damaged. Therefore, as shown in FIGS. 9-12, a plurality of openings T2 may be formed in the first metal layer M3 to reduce the area of the physical part T1 of the first metal layer M3, and a plurality of openings U2 may be formed in the second metal layer M4 to reduce the area of the physical part U1 of the second metal layer M4. In such way, the risk of arc discharge when the first metal layer M3 and the second metal layer M4 are patterned in the vacuum machine may be reduced; and the overlapping area of the physical part T1 of the first metal layer M3 and the physical part U1 of the second metal layer M4 along the direction perpendicular to the plane of the base substrate sub may be reduced, thereby reducing the risk of short circuit between the first metal layer M3 and the second metal layer M4 when the insulating layer between the first metal layer M3 and the second metal layer M4 is damaged.

Different metal layers in the display panel may be isolated by the insulating layer which may not only play an isolation role but also play a protective and supporting role. Optionally, as shown in FIG. 6, an insulating layer PLN may be between the first metal layer M3 and the second metal layer M4. The insulating layer PLN may be an organic material layer, that is, the insulating layer PLN may be an organic insulating layer. Optionally, the insulating layer PLN may also be an inorganic material layer.

Compared with inorganic material layers as insulating layers, organic material layers as insulating layers may have lower manufacturing costs. In addition, organic material layers may have desirable chemical stability and physical properties which may resist erosion by environmental factors such as moisture and oxygen and be conducive to extending the service life of the display panel. Organic material layers may also have desirable flexibility and customization. However, the organic insulating layers may generate volatile gases in some high-temperature processes, and exhaust design may be required. In the display panel provided in embodiments of the present disclosure, the plurality of openings T2 may be formed in the first metal layer M3, and the plurality of openings U2 may be formed in the second metal layer M4, thereby being beneficial for exhaust design of the organic insulating layer between the first metal layer M3 and the second metal layer M4.

As shown in FIGS. 9-12, the display panel may include the first blocking region CC; and as disclosed above, the active layer q of the display panel may include the first active portion q1, the pixel circuit 10 may include the first active portion q1, the first active portion q1 may include the active portion of each thin-film transistor in the pixel circuit 10, and the first active portion q1 may be in the first blocking region CC. That is, the active portion of each thin-film transistor in the pixel circuit 10 may be in the first blocking region CC.

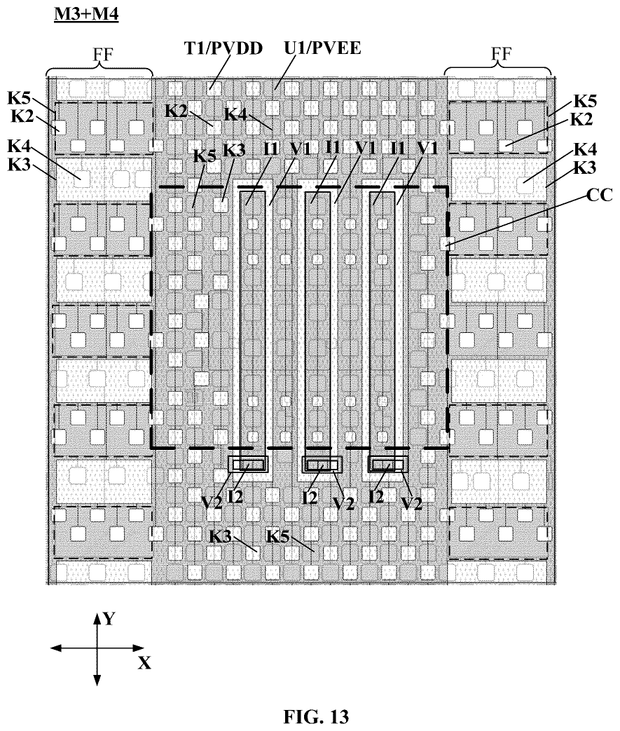

As shown in FIGS. 9-13, FIG. 13 illustrates a layout structural schematic of a stacked layer of the first metal layer M3 and the second metal layer M4 in FIG. 9; and along the direction perpendicular to the plane of the base substrate, at least one of the physical part T1 of the first metal layer M3 and the physical part U1 of the second metal layer M4 may cover the first blocking region CC, that is, cover the first active portion q1. In such way, when the laser bonding is performed on the light-emitting element, the active portion of each thin-film transistor in the pixel circuit 10 may be avoided to be affected, thereby avoiding affecting the performance of the pixel circuit 10 and ensuring normal light emission of the light-emitting element.

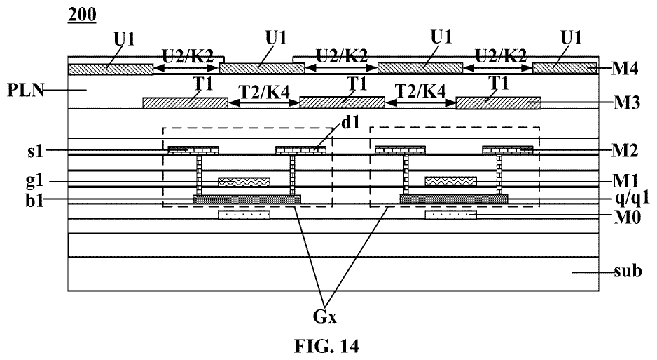

It may be understood that, as shown in FIGS. 9-14, FIG. 14 illustrates another partial cross-sectional view of the array substrate 200 in the display panel according to various embodiments of the present disclosure; and in the first blocking region CC, along the direction perpendicular to the plane of the base substrate, the openings T2 in the first metal layer M3 may be not overlapped with the openings U2 in the second metal layer M4; the openings T2 in the first metal layer M3 and the openings U2 in the second metal layer M4 may be arranged in an staggered and complementary manner, the opening T2 in the first metal layer M3 may be blocked by the physical part U1 in the second metal layer M4, and the opening U2 in the second metal layer M4 is blocked by the physical part T1 in the first metal layer M3. In such way, the first active layer q1 in the first blocking region CC may be avoided to be affected when the laser bonding is performed on the light-emitting element, thereby avoiding the influence on the performance of the pixel circuit 10 and ensuring normal light emission of the light-emitting element.

Furthermore, it may be understood that the active layer q may also include the second active portion, the shift register circuit 21 may include the second active portion, and along the direction perpendicular to the plane of the base substrate, at least one of the physical part T1 of the first metal layer M3 and the physical part U1 of the second metal layer M4 may also cover the second active portion. In such way, the second active portion of the shift register circuit 21 may be avoided to be affected when the laser bonding is performed on the light-emitting element, thereby avoiding affecting the performance of the shift register circuit 21 and the driving circuit 20.

From above-mentioned analysis, it may be seen that while increasing the area of the first power supply structure PVDD, it may also need to form the plurality of openings T2 in the first power supply structure PVDD; similarly, while increasing the area of the second power supply structure PVEE, it may also need to form the plurality of openings U2 in the second power supply structure PVEE. In such way, on the one hand, the area of the physical part T1 of the first metal layer M3 and the physical part U1 of the second metal layer M4 may be reduced, which may be convenient for patterning in the vacuum machine; on the other hand, the overlapping area of the physical part T1 of the first metal layer M3 and the physical part U1 of the second metal layer M4 along the direction perpendicular to the plane of the base substrate may be reduced, which may reduce the risk of short circuit; on the other hand, such design may be beneficial for sufficient exhaust. Furthermore, in order to avoid affecting the thin-film transistor in the pixel circuit 10 and the thin-film transistor in the shift register circuit 21 when laser bonding is performed on the light-emitting elements, at least one of the physical part T1 of the first metal layer M3 and the physical part U1 of the second metal layer M4 may need to cover the first active portion q1 of corresponding pixel circuit 10 and the second active portion of corresponding shift register circuit 21.

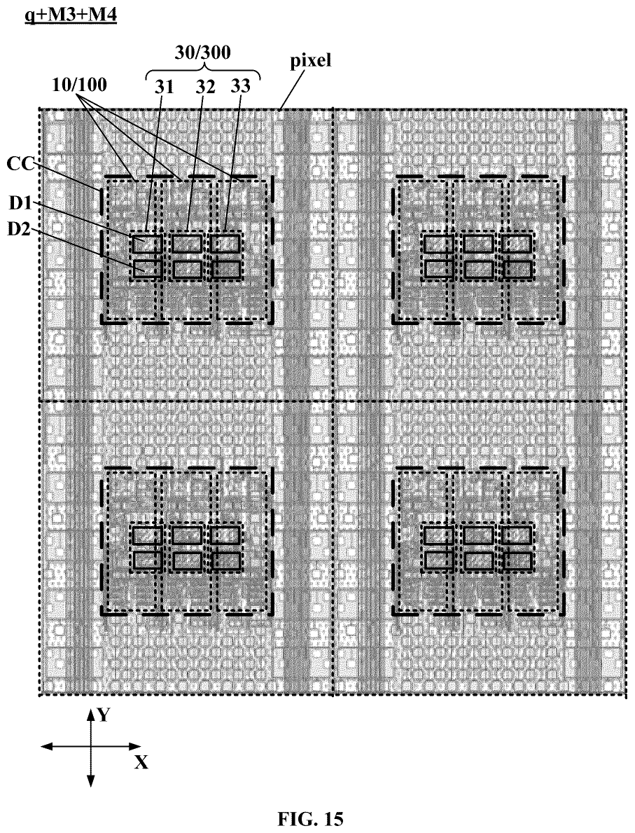

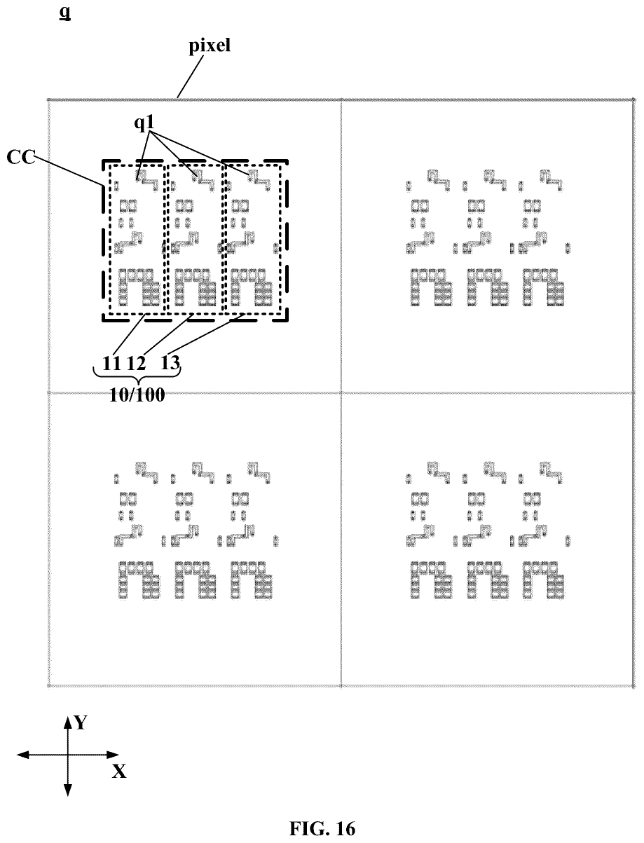

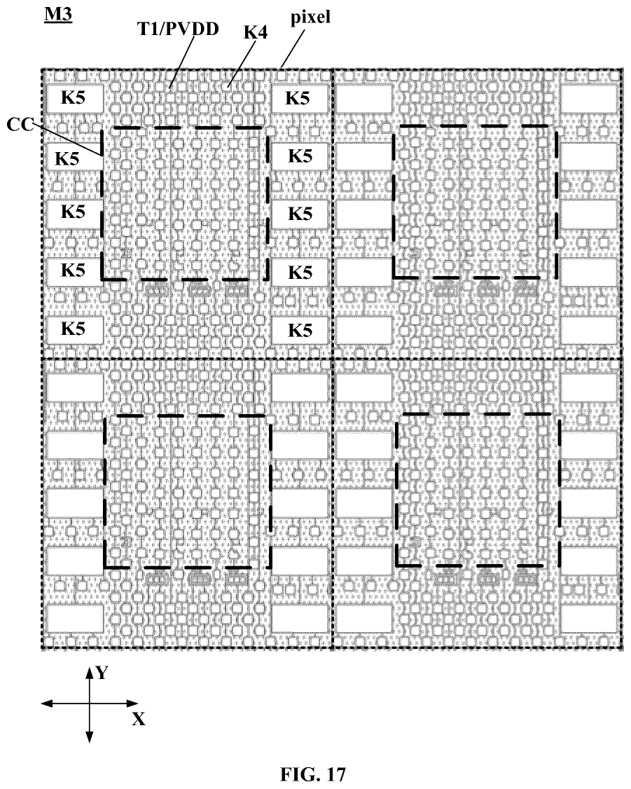

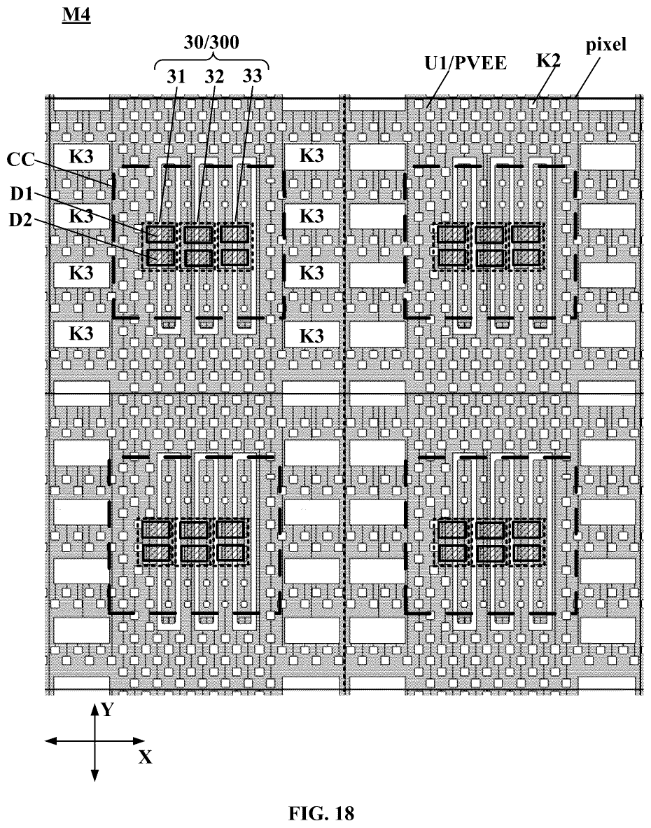

Based on the above, FIG. 15 illustrates another partial layout structural schematic of an A1 region in a middle display region of a display panel shown in FIG. 7. For the sake of clarity, FIG. 15 only shows the layout structure of the active layer q, the layout structure of the first metal layer M3, and the layout structure of the second metal layer M4. FIG. 16 further illustrates the layout structural schematic of the active layer q in FIG. 15, FIG. 17 further illustrates the layout structural schematic of the first metal layer M3 in FIG. 15, and FIG. 18 further illustrates the layout structural schematic of the second metal layer M4 in FIG. 15.

As shown in FIGS. 15-18, along the direction perpendicular to the plane of the base substrate sub, the first power supply structure PVDD may be at least partially overlapped with the four pixel circuit groups 100 including two adjacent rows of pixel circuit groups 100 and two adjacent columns of pixel circuit groups 100 which are overlapped with each other. Furthermore, optionally, as shown in FIGS. 15-18, the orthographic projection region of the first power supply structure PVDD on the plane of the base substrate sub may cover the orthographic projection area of the 2*2 pixel circuit group 100 on the plane of the base substrate sub.

As shown in FIGS. 15-18, along the direction perpendicular to the plane of the base substrate sub, the second power supply structure PVEE may be at least partially overlapped with the four pixel circuit groups 100 including two adjacent rows of pixel circuit groups 100 and two adjacent columns of pixel circuit groups 100 which are overlapped with each other. Furthermore, optionally, as shown in FIGS. 15-18, the orthographic projection area of the second power supply structure PVEE on the plane of the base substrate sub may cover the orthographic projection area of the 2*2 pixel circuit group 100 on the plane of the base substrate sub.

Similarly, the orthographic projection area of the first power supply structure PVDD on the plane of the base substrate sub may also cover the orthographic projection area of 3*3, 3*4, 4*3, 4*4 . . . and other different matrix pixel circuit groups 100 and the orthographic projection area of all pixel circuit groups 100 on the plane of the base substrate sub; and even the orthographic projection area of the first power supply structure PVDD on the plane of the base substrate sub may cover entire display region AA of the display panel. As the orthographic projection area of the first power supply structure PVDD on the plane of the base substrate sub increases, the area of the first power supply structure PVDD may increase, and the impedance of the first power supply structure PVDD may decrease, which may be more beneficial for improving the display brightness uniformity of the display panel.

Similarly, the orthographic projection area of the second power supply structure PVEE on the plane of the base substrate sub may also cover 3*3, 3*4, 4*3, 4*4 . . . and other different matrix pixel circuit groups 100 and the orthographic projection area of all pixel circuit groups 100 on the plane of the base substrate sub; and even the orthographic projection area of the second power supply structure PVEE on the plane of the base substrate sub may cover entire display region AA of the display panel. As the orthographic projection area of the second power supply structure PVEE on the plane of the base substrate sub increases, the area of the second power supply structure PVEE may increase, and the impedance of the second power supply structure PVEE may be decrease, which may be more beneficial for improving the display brightness uniformity of the display panel.

It should be noted that one pixel circuit group 100 and one light-emitting element group 300 may form one pixel unit. FIGS. 9-13 illustrate one pixel unit, and FIGS. 15-18 illustrate four pixel units. Above four pixel units may form a matrix of two rows and two columns (i.e., 2*2) along the first direction X and the second direction Y. In order to clearly distinguish different pixel units, in FIGS. 15-18, horizontal lines and vertical lines may be configured to indicate the boundaries of adjacent pixel unit areas along the first direction X and the second direction Y. It may be understood that boundaries may be only for the convenience of explanation and may be not intended to limit the present disclosure.

As shown in FIG. 2, the pixel circuit 100 may include the pulse width module PWM and the amplitude module PAM. Although the pulse width module PWM in the pixel circuit 100 is also connected to the turnoff voltage signal VDD-PWM, the turnoff voltage signal VDD-PWM may be similar to the first power supply voltage signal VPVDD. Since the amplitude module PAM directly drives the light-emitting element 30, the first power supply structure PVDD may be electrically connected to the amplitude module PAM of the pixel circuit 100. That is, the first power supply structure PVDD may provide the first power supply voltage signal VPVDD to the amplitude module PAM of the pixel circuit 100. In such way, by increasing the area of the first power supply structure PVDD, the brightness uniformity of the display panel may be more directly improved.

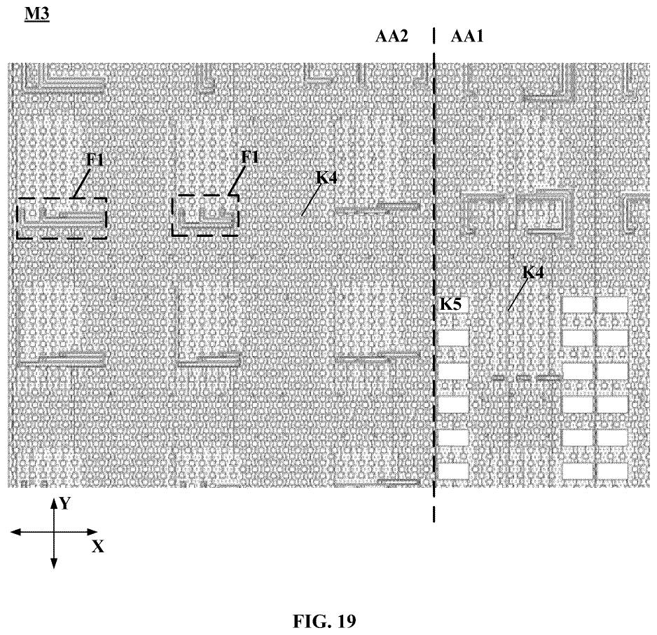

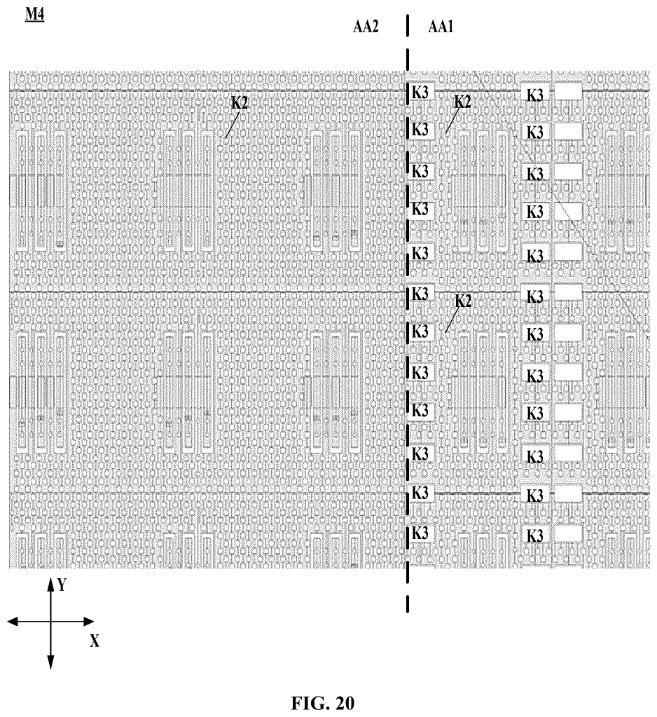

FIG. 19 illustrates a layout structural schematic of the first metal layer M3 in the A2 region of a display region adjacent to an edge of a display panel shown in FIG. 7; and FIG. 20 illustrates a layout structural schematic of the second metal layer M4 in the A2 region of a display region adjacent to an edge of a display panel shown in FIG. 7. Referring to FIGS. 4, 19 and 20, the display region AA of the display panel may include the first display region AA1 and the second display region AA2, and the second display region AA2 may at least partially surround the first display region AA1; the second display region AA2 may include the plurality of light-emitting element groups 300, the plurality of pixel circuit groups 100 and the driving circuit 20, and in the second display region AA2; along the direction perpendicular to the plane of the base substrate, the pixel circuit group 100 and the light-emitting element group 300 electrically connected to the pixel circuit group 100 may be not at least partially overlapped with each other; the first display region AA1 may include the plurality of light-emitting element groups 300 and the plurality of pixel circuit groups 100; and in the first display region AA1, along the direction perpendicular to the plane of the base substrate, the pixel circuit group 100 and the light-emitting element group 300 electrically connected to the pixel circuit group 100 may be at least partially overlapped with other.

It may be understood that, referring to FIGS. 4, 19 and 20, exemplarily, in the first display region AA1, along the direction perpendicular to the plane of the base substrate, the pixel circuit group 100 and the light-emitting element group 300 electrically connected to the pixel circuit group 100 may be at least partially overlapped with each other, such that the pixel circuit group 100 may be electrically connected to corresponding light-emitting element group 300. In the second display region AA2, the driving circuit 20 may be added, and the pixel circuit 10 may need to have a certain distance from the frame of the display panel. Therefore, along the direction perpendicular to the plane of the base substrate, the pixel circuit group 100 and the light-emitting element group 300 electrically connected to the pixel circuit group 100 may be configured to be not at least partially overlapped with each other.

It may also be understood that, referring to FIGS. 4, 19 and 20, in the second display region AA2, the pixel circuit group 100 and the light-emitting element group 300 electrically connected to the pixel circuit group 100 may be not at least partially overlapped with each other along the direction perpendicular to the plane of the base substrate. In order for the pixel circuit group 100 to be electrically connected to corresponding light-emitting element group 300, certain jump wires F1 may need to be configured. For example, multiple jump wires F1 may be configured in the first metal layer M3, such that the pixel circuit group 100 may be electrically connected to corresponding light-emitting element group 300.

Therefore, as shown in FIG. 20, in the second display region AA2, the openings of the second metal layer M4 may include the plurality of second openings K2; and in the first display region AA1, the openings of the second metal layer M4 may include the plurality of second openings K2 and the plurality of third openings K3, and the area of the third opening K3 may be greater than the area of the second opening K2. That is, the second metal layer M4 may be only configured with the plurality of small openings in the second display region AA2, while may be configured with large openings and small openings in the first display region AA1, which may be because the jump wires configured in the second display region AA2 may cut (split) corresponding metal layer. In order to maintain the integrity of the metal as possible to provide desirable power supply capacity, the second metal layer M4 may be only designed with small openings in the second display region AA2 near the edge of the display panel and may be designed with a combination of large openings and small openings in the first display region AA1 in the middle of the display panel.

As shown in FIGS. 9-13 and 15-20, in the first display region AA1, the pixel circuit group 100 may be configured with a wiring region FF on at least one side along the first direction X. Optionally, the pixel circuit group 100 may be configured with wiring regions FF on two sides along the first direction X. The wiring region FF may include signal lines extending along the second direction Y, for example, data signal lines for transmitting data signals to the pixel circuit 10, and signal lines for transmitting driving signals to the driving circuit 20 (e.g., the shift register circuit 21 in the driving circuit 20). Since the wiring region FF is not configured with the active layer q, the wiring region FF may not have the requirement to be completely covered by the physical part T1 of the first metal layer M3 and the physical part U1 of the second metal layer M4. In the first display region AA1, the second metal layer M4 may be configured with the third openings K3 with a relatively large area in the wiring region FF; that is, the third openings K3 may be in the wiring region FF, and the third openings K3 may be arranged in the wiring region FF along the second direction Y.

Furthermore, the second metal layer M4 may be configured with certain third openings K3 with a relatively large area in the wiring region FF, which may reduce the area of the physical part U1 of the second metal layer M4 to facilitate patterning in the vacuum machine, reduce the overlapping area of the physical part T1 of the first metal layer M3 and the physical part U1 of the second metal layer M4, reduce the risk of short circuit between two above physical parts, and further reduce the coupling between the physical part U1 of the second metal layer M4 (e.g., the second power supply structure PVFF) and the signal line in the wiring region FF.

In such way, the sub-display region AA0 may at least partially overlapped with the first display region AA1, such that the alignment mark R and the clearance region H around the alignment mark R may be in the third opening K3 with a relatively large area in the second metal layer M4.

As shown in FIGS. 9-13 and 15-20, in the second metal layer M4, in addition for the third opening K3 in the wiring region FF and the opening V1 between the second power supply structure PVEE and the first auxiliary electrode I1, other regions may be configured with the second openings K2. That is, the second openings K2 may be evenly arranged in entire display region AA, which may be beneficial for improving etching uniformity and reflection (effect) uniformity of the display panel. In addition, the second opening K2 with a relatively small area may be configured on the first auxiliary electrode I1.

As shown in FIGS. 9-13 and 15-20, in the first display region AA1, along the second direction Y, the third openings K3 and the plurality of second openings K2 may be arranged alternately. That is, in the wiring region FF, the second metal layer M4 may be also configured with the plurality of second openings K2 between the third openings K3 adjacent to each other along the second direction Y. In such way, the second metal layer M4 may not only be configured certain third openings K3 with an area greater than the second openings K2 in the wiring region FF, but also the plurality of second openings K2 may be retained, such that the pattern density of the second metal layer M4 in the wiring region FF and the pattern density of the second metal layer M4 in the first blocking region CC may be relatively uniform, which may be beneficial for improving etching uniformity and reflection uniformity of the display panel.

It should be noted that, referring to FIGS. 9-13 and FIGS. 15-20, the area of the third opening K3 may be greater than the area of the second opening K2. Optionally, the length of the third opening K3 along the first direction X may be greater than the length of the second opening K2 along the first direction X. In such way, along the first direction X, the third openings K3 may be overlapped with the plurality of second openings K2. Optionally, the width of the third opening K3 along the second direction Y may be greater than the width of the second opening K2 along the second direction Y. In such way, along the second direction Y, the third openings K3 may be overlapped with the plurality of second openings K2. Optionally, the length of the third opening K3 along the first direction X may be greater than the length of the second opening K2 along the first direction X, and the width of the third opening K3 along the second direction Y may be greater than the width of the second opening K2 along the second direction Y. In such way, along the first direction X and the second direction Y, the third openings K3 may all be overlapped with the plurality of second openings K2. As disclosed above, along the first direction X and/or the second direction Y, the third openings K3 may be overlapped with the plurality of second openings K2.

Similarly, as shown in FIG. 19, in the second display region AA2, the openings of the first metal layer M3 may include the plurality of fourth openings K4; and in the first display region AA1, the openings of the first metal layer M3 may include the plurality of fourth openings K4 and the plurality of fifth openings K5, and the area of the fifth openings K5 may be greater than the area of the fourth openings K4. In other words, the first metal layer M3 may be only configured with the plurality of small openings in the second display region AA2, while may be configured with large openings and small openings in the first display region AA1, which may be because the jump wires configured in the second display region AA2 may cut (split) corresponding metal layer. In order to maintain the integrity of the metal as possible to provide desirable power supply capacity, the first metal layer M3 may be only designed with small openings in the second display region AA2 near the edge of the display panel and may be designed with a combination of large openings and small openings in the first display region AA1 in the middle of the display panel.

As shown in FIGS. 9-13 and 15-20, in the first display region AA1, the pixel circuit group 100 may be configured with the wiring region FF on at least one side along the first direction X. Optionally, the pixel circuit group 100 may be configured with the wiring regions FF on two sides along the first direction X. The wiring region FF may include signal lines extending along the second direction Y, for example, data signal lines for transmitting data signals to the pixel circuit 10, and signal lines for transmitting driving signals to the driving circuit 20 (e.g., the shift register circuit 21 in the driving circuit 20). Since the wiring region FF is not configured with the active layer q, the wiring region FF may not have the requirement to be completely covered by the physical part T1 of the first metal layer M3 and the physical part U1 of the second metal layer M4. In the first display region AA1, the first metal layer M3 may be configured with the fifth openings K5 with a relatively large area in the wiring region FF; that is, the fifth openings K5 may be in the wiring region FF, and the fifth openings K5 may be arranged in the wiring region FF along the second direction Y.

In addition, the first metal layer M3 may be configured with certain fifth openings K5 with a relatively large area in the wiring region FF, which may reduce the area of the physical part T1 of the second metal layer M3 to facilitate patterning in the vacuum machine, reduce the overlapping area of the physical part T1 of the first metal layer M3 and the physical part U1 of the second metal layer M4, reduce the risk of short circuit between two above physical parts, and further reduce the coupling between the physical part T1 of the first metal layer M3 (e.g., the first power supply structure PVEE) and the signal line in the wiring region FF.

In such way, the sub-display region AA0 may be at least partially overlapped with the first display region AA1, such that the alignment mark R and the clearance region H around the alignment mark R may be in the fifth opening K5 with a relatively large area in the first metal layer M3.

As shown in FIGS. 9-13 and 15-20, in the first metal layer M3, in addition to the fifth opening K5 in the wiring region FF and the opening V2 between the first power supply structure PVDD and the second auxiliary electrode I2, other regions may be configured with the fourth openings K4; that is, the fourth openings K4 may be evenly arranged in entire display region AA, which may be beneficial for improving etching uniformity and reflection uniformity of the display panel.

As shown in FIGS. 9-13 and 15-20, in the first display region AA1, the fifth openings K5 and the plurality of fourth openings K4 may be arranged alternately along the second direction Y; that is, the first metal layer M3 may be configured with the plurality of fourth openings K4 between the fifth openings K5 adjacent to each other along the second direction Y in the wiring region FF. In such way, the first metal layer M3 may not only be configured with certain fifth openings K5 with an area greater than the fourth openings K4 provided in the wiring region FF, but also the plurality of fourth openings K4 may be retained, such that the pattern density of the first metal layer M3 in the wiring region FF and the pattern density of the first metal layer M3 in the first blocking region CC may be relatively uniform, which may be beneficial for improving etching uniformity and reflection uniformity of the display panel.

It should be noted that, referring to FIGS. 9-13 and FIGS. 15-20, the area of the fifth opening K5 may be greater than that of the fourth opening K4. Optionally, the length of the fifth opening K5 along the first direction X may be greater than the length of the fourth opening K4 along the first direction X. In such way, along the first direction X, the fifth opening K5 may be overlapped with the plurality of fourth openings K4. Optionally, the width of the fifth opening K5 along the second direction Y may be greater than the width of the fourth opening K4 along the second direction Y. In such way, along the second direction Y, the fifth opening K5 may be overlapped with the plurality of fourth openings K4. Optionally, the length of the fifth opening K5 along the first direction X may be greater than the length of the fourth opening K4 along the first direction X, and the width of the fifth opening K5 along the second direction Y may be greater than the width of the fourth opening K4 along the second direction Y. In such way, along the first direction X and the second direction Y, the fifth opening K5 may be overlapped with the plurality of fourth openings K4. As disclosed above, along the first direction X and/or the second direction Y, the fifth opening K5 may be overlapped with the plurality of fourth openings K4.

Optionally, referring to FIGS. 9-13 and FIGS. 15-20, opening designs of the first metal layer M3 and the second metal layer M4 may be combined. For example, in the second display region AA2, the openings of the second metal layer M4 may include the plurality of second openings K2; and in the first display region AA1, the openings of the second metal layer M4 may include the plurality of second openings K2 and the plurality of third openings K3, and the area of the third opening K3 may be greater than the area of the second opening K2. That is, the second metal layer M4 may be only designed with small openings in the second display region AA2 near the edge of the display panel, while the first display region AA1 in the middle of the display panel may be designed with a combination of large openings and small openings.

Meanwhile, in the second display region AA2, the openings of the first metal layer M3 may include the plurality of fourth openings K4; and in the first display region AA1, the openings of the first metal layer M3 may include the plurality of fourth openings K4 and the plurality of fifth openings K5, and the area of the fifth opening K5 may be greater than the area of the fourth opening K4. That is, the first metal layer M3 may be only designed with small openings in the second display region AA2 near the edge of the display panel, while the first display region AA1 in the middle of the display panel may be designed with a combination of large openings and small openings.

As shown in FIGS. 9-13 and 15-20, in the first display region AA1, the pixel circuit group 100 may be configured with the wiring region FF on at least one side along the first direction X. Optionally, the pixel circuit group 100 may be configured with the wiring regions FF on two sides along the first direction X. The wiring region FF may include signal lines extending along the second direction Y, for example, data signal lines for transmitting data signals to the pixel circuit 10, and signal lines for transmitting driving signals to the driving circuit 20 (e.g., the shift register circuit 21 in the driving circuit 20). Since the wiring region FF is not configured with the active layer q, the wiring region FF may not have the requirement to be completely covered by the physical part T1 of the first metal layer M3 and the physical part U1 of the second metal layer M4. In the first display region AA1, the second metal layer M4 may be configured with the third openings K3 with a relatively large area in the wiring region FF; that is, the third openings K3 may be in the wiring region FF and arranged in the wiring region FF along the second direction Y.

Meanwhile, in the first display region AA1, the first metal layer M3 may be configured with the fifth openings K5 with a relatively large area in the wiring region FF; that is, the fifth openings K5 may be in the wiring region FF and arranged along the second direction Y in the wiring region FF.

As shown in FIGS. 9-13 and 15-20, the orthographic projections of the third openings K3 in the second metal layer M4 may be alternately arranged with the fifth openings K5 in the first metal layer M3 along the second direction Y. In such way, the area of the physical part T1 of the first metal layer M3 and the area of the physical part U1 of the second metal layer M4 may be both reduced which may be convenient for patterning in the vacuum machine; the overlapping area of the physical part T1 of the first metal layer M3 and the physical part U1 of the second metal layer M4 may be reduced which may reduce the risk of short circuit between above two portions; and the coupling between the physical part T1 of the first metal layer M3 (e.g., the first power supply structure PVDD) and the signal line in the wiring region FF, and the coupling between the physical part U1 of the second metal layer M4 (e.g., the second power supply structure PVEE) and the signal line in the wiring region FF may be reduced.

In such way, the sub-display region AA0 may be at least partially overlapped with the first display region AA1, such that the alignment mark R and the clearance region H around the alignment mark R may be in the third opening K3 with a relatively large area in the second metal layer M4, or in the fifth opening K5 with a relatively large area in the first metal layer M3.

As shown in FIGS. 9-13 and 15-20, in the second metal layer M4, in addition to the third opening K3 in the wiring region FF and the opening V1 between the second power supply structure PVEE and the first auxiliary electrode I1, other regions may be configured with the second openings K2. That is, the second openings K2 may be evenly arranged in entire display region AA, which may be beneficial for improving etching uniformity and reflection uniformity of the display panel. In addition, the second opening K2 with a relatively small area may be configured on the first auxiliary electrode I1.

As shown in FIGS. 9-13 and 15-20, in the first metal layer M3, in addition to the fifth opening K5 in the wiring region FF and the opening V2 between the first power supply structure PVDD and the second auxiliary electrode I2, other regions may be configured with the fourth openings K4. That is, the fourth openings K4 may be evenly arranged in entire display region AA, which may be beneficial for improving etching uniformity and reflection uniformity of the display panel.

Furthermore, optionally, referring to FIGS. 9-13 and 15-20, in the first display region AA1, along the second direction Y, the third openings K3 and the plurality of second openings K2 may be alternately arranged. That is, the second metal layer M4 may be in the wiring region FF, and the plurality of second openings K2 may be also configured between adjacent third openings K3 along the second direction Y. In such way, the second metal layer M4 may not only be configured with certain third openings K3 with an area greater than the second openings K2 in the wiring region FF, but also the plurality of second openings K2 may be retained, such that the pattern density of the second metal layer M4 in the wiring region FF and the pattern density of the second metal layer M4 in the first blocking region CC may be relatively uniform, which may be beneficial for improving etching uniformity and reflection uniformity of the display panel.

Meanwhile, referring to FIGS. 9-13 and FIGS. 15-20, in the first display region AA1, along the second direction Y, the fifth openings K5 and the plurality of fourth openings K4 may be arranged alternately. That is, the first metal layer M3 may be in the wiring region FF, and the plurality of fourth openings K4 may be also configured between adjacent fifth openings K5 along the second direction Y. In such way, certain fifth openings K5 with an area greater than the fourth openings K4 in the wiring region FF may be not only configured in the first metal layer M3, but also the plurality of fourth openings K4 may be retained, such that the pattern density of the first metal layer M3 in the wiring region FF and the pattern density of the first metal layer M3 in the first blocking region CC may be relatively uniform, which may be beneficial for improving etching uniformity and reflection uniformity of the display panel.

As shown in FIGS. 9-13 and 15-20, optionally, the orthographic projection of the third opening K3 on the first metal layer M3 may be overlapped with the plurality of fourth openings K4 between two adjacent fifth openings K5. Optionally, the orthographic projection of the fifth opening K5 on the second metal layer M4 may be overlapped with the plurality of second openings K2 between two adjacent third openings K3. Optionally, the orthographic projection of the third opening K3 on the first metal layer M3 may be overlapped with the plurality of fourth openings K4 between two adjacent fifth openings K5, and the orthographic projection of the fifth opening K5 on the second metal layer M4 may be overlapped with the plurality of second openings K2 between two adjacent third openings K3.

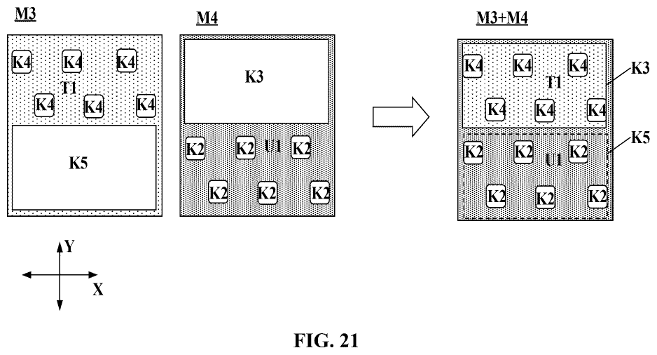

To clearly understand the present disclosure, FIG. 21 illustrates a partial enlarged schematic of the first metal layer M3 and the second metal layer M4 in the wiring region FF. It may be seen that in the wiring region FF, the fifth openings K5 and the orthographic projections of the third openings K3 on the first metal layer M3 may be arranged in an staggered and complementary manner; the orthographic projection of the third opening K3 on the first metal layer M3 may be overlapped with the plurality of fourth openings K4 between two adjacent fifth openings K5; and the orthographic projection of the fifth opening K5 on the second metal layer M4 may be overlapped with the plurality of second openings K2 between two adjacent third openings K3.

It may be understood that the orthographic projection of the third opening K3 on the first metal layer M3 may be overlapped with the plurality of fourth openings K4 between two adjacent fifth openings K5; and/or the orthographic projection of the fifth opening K5 on the second metal layer M4 may be overlapped with the plurality of second openings K2 between two adjacent third openings K3, which may further reduce the overlapping area between the physical part T1 of the first metal layer M3 and the physical part U1 of the second metal layer M4, thereby being beneficial for gas exhaust, and may further reduce the coupling between the physical part T1 of the first metal layer M3 (e.g., the first power supply structure PVDD) and the signal line in the wiring region FF, and the coupling between the physical part U1 of the second metal layer M4 (e.g., the second power supply structure PVEE) and the signal line in the wiring region FF. In addition, the pattern density of the first metal layer M3 in the wiring region FF and the pattern density of the first metal layer M3 in the first blocking region CC may be relatively uniform, and the pattern density of the second metal layer M4 in the wiring region FF and the pattern density of the second metal layer M4 in the first blocking region CC may be also relatively uniform, which may be beneficial for improving etching uniformity and reflection uniformity of the display panel.

Moreover, referring to FIGS. 9-21, in the first blocking region CC, in order to block the first active portion q1, it may configure that the second opening K2 of the second metal layer M4 may be not overlapped with the fourth opening K4 of the first metal layer M3 along the direction perpendicular to the plane of the base substrate, the second openings K2 of the second metal layer M4 may be arranged uniformly in entire display region AA, and the fourth openings K4 of the first metal layer M3 may be also arranged uniformly in entire display region AA. Therefore, in overall display region AA, along the direction perpendicular to the plane of the base substrate, the second openings K2 of the second metal layer M4 may be not overlapped with the fourth openings K4 of the first metal layer M3, such that the second active portion of the driving circuit and the active portion of other thin-film transistors may also be blocked.

As disclosed above, the sub-display region AA0 may be at least partially overlapped with the first display region AA1, such that the alignment mark R and the clearance region H around the alignment mark R may be in the third opening K3 with a relatively large area in the second metal layer M4, or may be in the fifth opening K5 with a relatively large area in the first metal layer M3, which may be described in detail hereinafter.

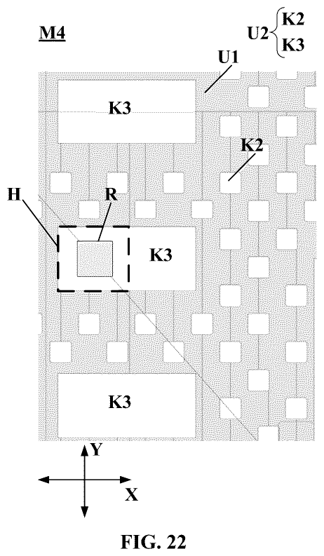

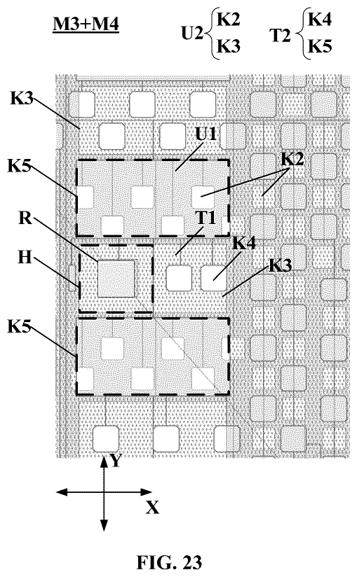

FIG. 22 illustrates a partial layout structural schematic of the second metal layer M4 at the wiring region in a display panel according to various embodiments of the present disclosure; and FIG. 23 illustrates a layout structural schematic of a stacked layer of the first metal layer M3 and the second metal layer M4 in FIG. 22. Referring to FIGS. 22-23, the alignment mark R may be in the second metal layer M4, and the opening U2 of the second metal layer M4 may include the clearance region H.

As shown in FIGS. 22-23, optionally, the third opening K3 of the second metal layer M4 may include the clearance region H; that is, the alignment mark R and the clearance region H around the alignment mark R may be in the third opening K3 of the second metal layer M4.

As shown in FIGS. 22-23, optionally, the orthographic projection of the alignment mark R and the clearance region H around the alignment mark R on the first metal layer M3 may be in the physical part T1 of the first metal layer M3; that is, no opening may be configured in the range of the orthographic projection of the alignment mark R and the clearance region H around the alignment mark R on the first metal layer M3.

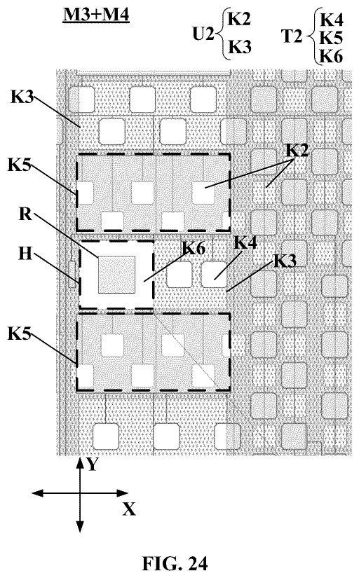

Referring to FIGS. 22 and 24, FIG. 24 illustrates another layout structural schematic of a stacked layer of the first metal layer M3 and the second metal layer M4 in FIG. 22. Optionally, the orthographic projection of the alignment mark R and the clearance region H around the alignment mark R on the first metal layer M3 may be in the opening T2 of the first metal layer M3. For example, the opening T2 of the first metal layer M3 may also include the sixth opening K6, and the orthographic projection of the alignment mark R and the clearance region H around the alignment mark R on the first metal layer M3 may be in the sixth opening K6 of the first metal layer M3. The sixth opening K6 may be an opening different from the fourth opening K4 and the fifth opening K5.

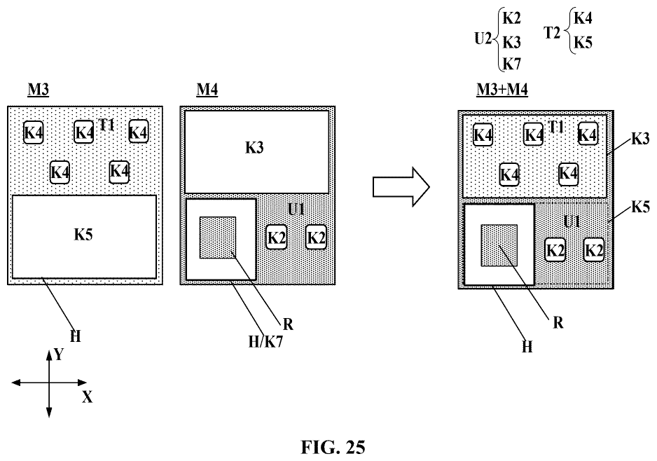

FIG. 25 illustrates another partial enlarged schematic of the first metal layer M3 and the second metal layer M4 in a wiring region FF. As shown in FIG. 25, the alignment mark R may be in the second metal layer M4, but the alignment mark R may be not in the third opening K3. At this point, the openings U2 of the second metal layer M4 may also include the seventh opening K7; the alignment mark R and the clearance region H around the alignment mark R may be in the seventh opening K7; the orthographic projection of the alignment mark R and the clearance region H around the alignment mark R on the first metal layer M3 may be in the fifth opening K5; and the seventh opening K7 may be an opening different from the second opening K2 and the third opening K3.

It may be understood that the organic insulating layer may be between the first metal layer M3 and the second metal layer M4, such that the organic insulating layer may be between the first metal layer M3 and the second metal layer M4 to support the alignment mark R in FIGS. 24-25. However, the orthographic projection of the alignment mark R and the clearance region H around the alignment mark R on the first metal layer M3 may be in the physical part T1, which may make the alignment mark R more stable than being in the opening T2 of the first metal layer M3.

It may also be understood that the orthographic projection of the alignment mark R and the clearance region H around the alignment mark R on the first metal layer M3 may be in the physical part T1 or in the opening U2 of the first metal layer M3. In such way, when the second metal layer M4 is viewed from the side of the second metal layer M4 away from the substrate, there may be only one alignment mark R (one shape) within the alignment mark R and the clearance region H around the alignment mark R, thereby accurately identifying the alignment mark R.

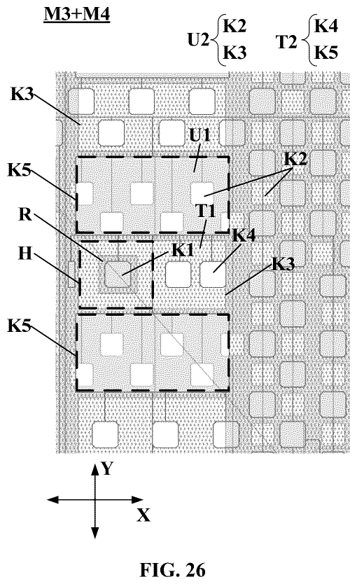

Referring to FIGS. 22 and 26, FIG. 26 illustrates another layout structural schematic of a stacked layer of the first metal layer M3 and the second metal layer M4 in FIG. 22. Optionally, the orthographic projection of the clearance region H around the alignment mark R on the first metal layer M3 may be in the physical part T1 of the first metal layer M3; the openings of the first metal layer M3 may include the first opening K1; and the first opening K1 may be covered by the alignment mark R along the direction perpendicular to the plane of the base substrate.

As disclosed above, in the first metal layer M3, the fourth openings K4 may be uniformly arranged in entire display region AA; and the orthographic projection of the third opening K3, which is in the second metal layer M4, on the first metal layer M3 may be overlapped with the plurality of fourth openings K4 between two adjacent fifth openings K5, which may reduce the overlapping area between the physical part T1 of the first metal layer M3 and the physical part U1 of the second metal layer M4, thereby being beneficial to gas exhaust. After the alignment mark R is configured in the third opening K3 of the second metal layer M4, since the clearance region H needs to be configured around the alignment mark R, if the orthographic projection of the clearance region H around the alignment mark R on the first metal layer M3 is in the physical part T1 of the first metal layer M3, at least a part of the first metal layer M3 corresponding to the clearance region H may not be configured with an opening. Furthermore, if the clearance region H around the alignment mark R is relatively small, it may cause difficulty in identifying and misjudging the alignment mark R. If the clearance region H around the alignment mark R is relatively large, a part of the first metal layer M3 corresponding to the alignment mark R and the clearance region H around the alignment mark R may be a continuous metal covering region; and such part of continuous metal covering region may have a peeling problem due to insufficient exhaust.

Based on the above, the openings configured in the first metal layer M3 may include the first opening K1; and along the direction perpendicular to the plane of the base substrate, the first opening K1 may be covered by the alignment mark R. In such way, when the second metal layer M4 is viewed from the side of the second metal layer M4 away from the substrate, there may be only one alignment mark R in the range of the alignment mark R and the clearance region H around the alignment mark R, such that the alignment mark R may be accurately identified; and a part of the first metal layer M3 corresponding to the alignment mark R and the clearance region H around the alignment mark R may be configured with the first opening K1, which may avoid metal peeling problem, thereby being beneficial for sufficient exhaust.

Furthermore, optionally, in some embodiments of the present disclosure, the geometric center of the first opening K1 may be coincided with the geometric center of the orthographic projection of the alignment mark R on the first metal layer M3. If the geometric center of the first opening K1 is not coincided with the geometric center of the orthographic projection of the alignment mark R on the first metal layer M3, the organic insulating layer PLN between the alignment mark R and the first opening K1 may be uneven due to the organic insulating layer PLN between the first metal layer M3 and the second metal layer M4, which may further cause the alignment mark R to be uneven and result in insufficient stability and accuracy of the alignment mark R. However, setting the geometric center of the first opening K1 to be coincided with the geometric center of the orthographic projection of the alignment mark R on the first metal layer M3 may make the alignment mark R to be even, which may improve the stability of the alignment mark R and be beneficial for accurate identification of the alignment mark R.

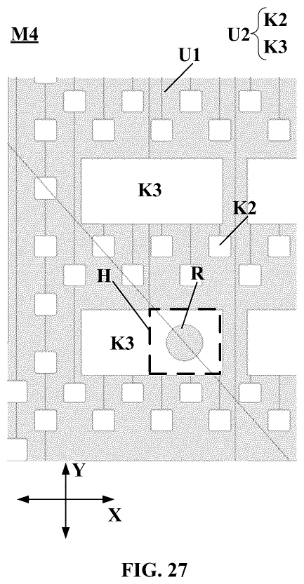

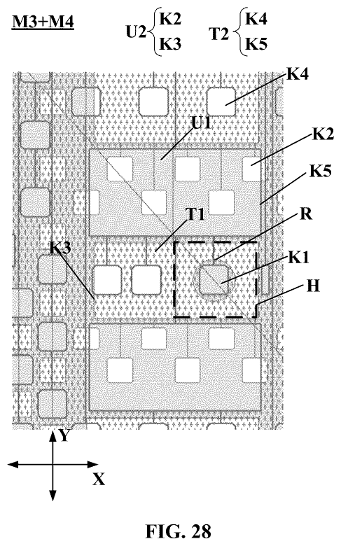

FIG. 27 illustrates another partial layout structural schematic of the second metal layer M4 at the wiring region FF in the display panel according to various embodiments of the present disclosure; and FIG. 28 illustrates a layout structural schematic of a stacked layer of the first metal layer M3 and the second metal layer M4 in FIG. 27. Unlike rectangular alignment mark R in FIGS. 22 and 26, the alignment mark R in FIGS. 27-28 may be circular. Other parts in FIGS. 27-28 may refer to the description of FIGS. 22 and 26, which may not be described in detail herein.

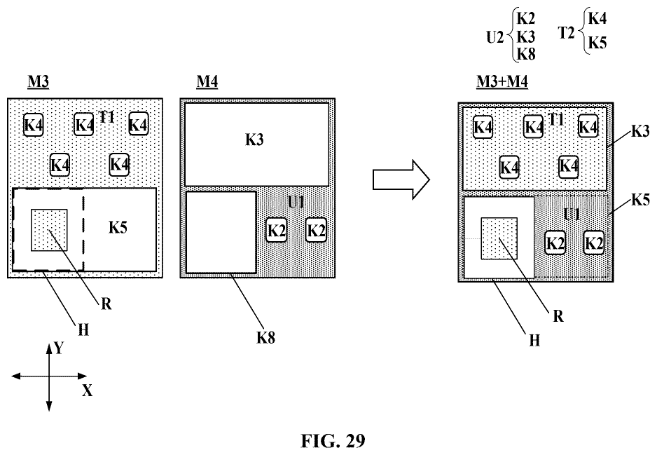

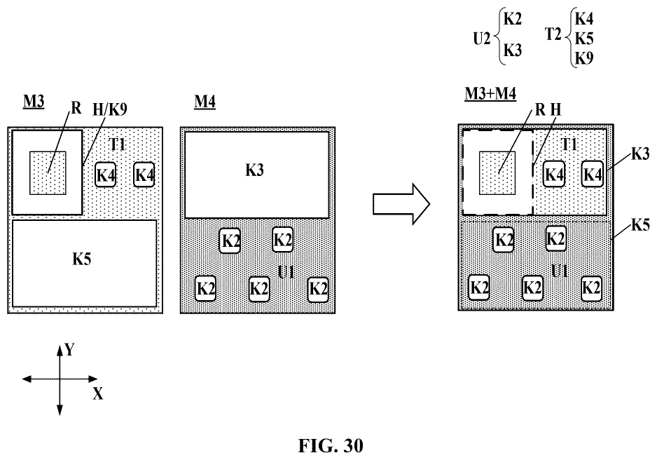

FIG. 29 illustrates another partial enlarged schematic of the first metal layer M3 and the second metal layer M4 in the wiring region FF; and FIG. 30 illustrates another partial enlarged schematic of the first metal layer M3 and the second metal layer M4 in the wiring region FF. As shown in FIGS. 29-30 , the alignment mark R may also be in the first metal layer M3, the opening U2 of the first metal layer M3 may include the clearance region H, and the opening of the second metal layer M4 may expose the alignment mark R and the clearance region H around the alignment mark R along the direction perpendicular to the plane of the base substrate.

Optionally, as shown in FIG. 29, the alignment mark R and the clearance region H around the alignment mark R may be in the fifth opening K5 of the first metal layer M3. At this point, the openings U2 of the second metal layer M4 may also include the eighth opening K8. Along the direction perpendicular to the plane of the base substrate, the eighth opening K8 of the second metal layer M4 may expose the alignment mark R and the clearance region H around the alignment mark R. The eighth opening K8 may be an opening different from the second opening K2 and the third opening K3.

Optionally, as shown in FIG. 30, the openings T2 of the first metal layer M3 may further include the ninth opening K9; the alignment mark R and the clearance region H around the alignment mark R may be in the ninth opening K9 of the first metal layer M3; the orthographic projection of the alignment mark R and the clearance region H around the alignment mark R on the second metal layer M4 may be in the third opening K3; and the ninth opening K9 may be an opening different from the fourth opening K4 and the fifth opening K5.

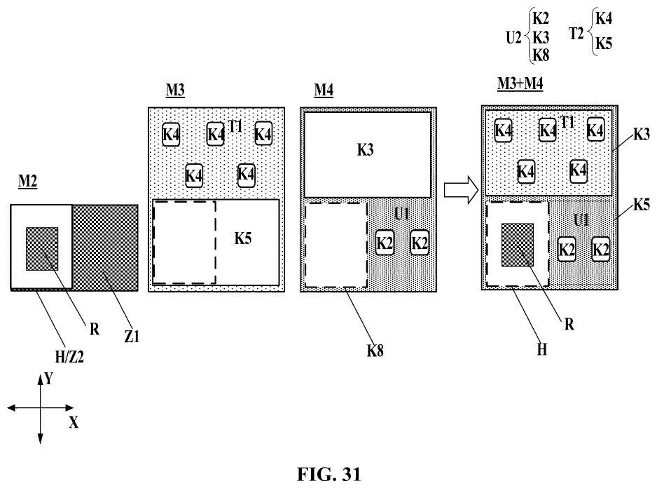

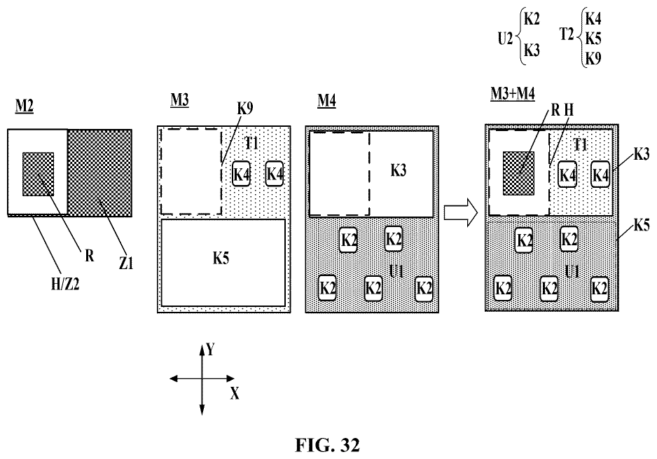

As shown in FIG. 6, the plurality of metal layers on the side of the active layer q away from the base substrate sub may also include the third metal layer M2; and the third metal layer M2 may be on the side of the first metal layer M3 facing the base substrate sub. FIG. 31 illustrates a partial enlarged schematic of the third metal layer M2, the first metal layer M3 and the second metal layer M4 in the wiring region FF; and FIG. 32 illustrates another partial enlarged schematic of the third metal layer M2, the first metal layer M3 and the second metal layer M4 in the wiring region FF. As shown in FIGS. 31-32, the third metal layer M2 may also include a physical part Z1 and a plurality of openings Z2, the alignment mark R may also be in the third metal layer M2, and the opening Z2 of the third metal layer M2 may include the clearance region H.

Optionally, as shown in FIG. 31, the orthographic projection of the alignment mark R and the clearance region H around the alignment mark R on the third metal layer M2 may be in the fifth opening K5 of the first metal layer M3; and the openings U2 of the second metal layer M4 may also include the eighth opening K8. Along the direction perpendicular to the plane of the base substrate, the eighth opening K8 of the second metal layer M4 and the fifth opening K5 of the first metal layer M3 may expose the alignment mark R on the third metal layer M2 and the clearance region H around the alignment mark R.

Optionally, as shown in FIG. 32, the openings T2 of the first metal layer M3 may also include the ninth opening K9. Along the direction perpendicular to the plane of the base substrate, the ninth opening K9 of the first metal layer M3 and the third opening K3 of the second metal layer M4 may expose the alignment mark R of the third metal layer M2 and the clearance region H around the alignment mark R.

It should be noted that above-mentioned embodiments describe that the alignment mark R and the clearance region H around the alignment mark R may be respectively in the opening U2 of the second metal layer M4, in the opening T2 of the first metal layer M3, and in the opening Z2 of the third metal layer M2, which may provide a variety of designs for the arrangement of the alignment mark R and the clearance region H around the alignment mark R to adapt to various actual situations.

It should also be noted that, the first metal layer M3 and the second metal layer M4 may be disposed with relatively large-area openings in the wiring region FF, such that the alignment mark R and the clearance region H around the alignment mark R being in the wiring region FF may be taken as an example for description in above-mentioned embodiments. It may be understood that, the wiring region FF may be not configured with the active layer q; therefore, when the alignment mark R and the clearance region H around the alignment mark R is in the wiring region FF, the alignment mark R and the clearance region H may be not overlapped with the active layer q along the direction perpendicular to the plane of the base substrate, and the clearance region H may be prevented from exposing the active layer q, which may not be limited in the present disclosure. As shown in FIG. 8, when the plurality of metal layers on the side of the active layer q away from the base substrate sub blocks the active layer q, that is, when the active layer q is not damaged by the laser bonding is performed on the light-emitting element, the alignment mark R and the clearance region H may be also overlapped with the active layer q along the direction perpendicular to the plane of the base substrate, which may depend on actual situations.

It should be noted that the alignment mark R and the clearance region H around the alignment mark R being in the first display region AA1 may be taken as an example for description in embodiments of the present disclosure, which may be not limited in the present disclosure. Optionally, the alignment mark R and the clearance region H around the alignment mark R may also be configured in the second display region AA2 other than the region where the jump wire F1 is configured.

Based on any of above-mentioned embodiments, optionally, in some embodiments of the present disclosure, as shown in FIG. 7, at least two alignment marks R in the sub-display region AA0 may include at least one alignment mark group R10; and the alignment mark group R10 may include two alignment marks R.

Optionally, as shown in FIG. 7, when at least two alignment marks R in the sub-display region AA0 include one alignment mark group R10, the line connecting the geometric centers of two alignment marks R in the alignment mark group R10 may intersect the first direction X and the second direction Y; that is, the line connecting the geometric centers of two alignment marks R in the alignment mark group R10 may need to be able to construct an X-Y coordinate system, thereby being convenient to accurately identify the bonding positions of each light-emitting element according to alignment situations.

Furthermore, optionally, as shown in FIG. 7, when at least two alignment marks R in the sub-display region AA0 include one alignment mark group R10, the line connecting the geometric centers of two alignment marks R in the alignment mark group R10 may be coincided with a diagonal line of the sub-display region AA0, such that the alignment accuracy of the alignment marks R may be improved. Moreover, as shown in FIG. 7, the shapes of two alignment marks R in the alignment mark group R10 may be different. For example, one alignment mark R in the alignment mark group R10 may be rectangular, and another alignment mark R may be circular. In such way, the alignment accuracy of the alignment mark R may not only be improved, and the front and back of the alignment may also be identified during alignment.

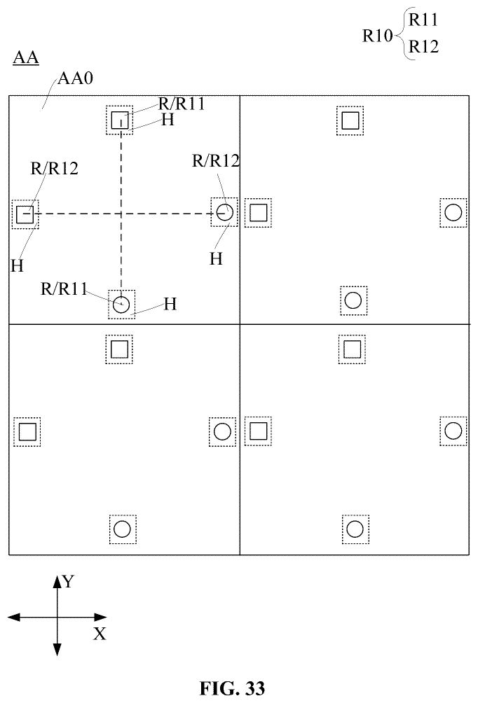

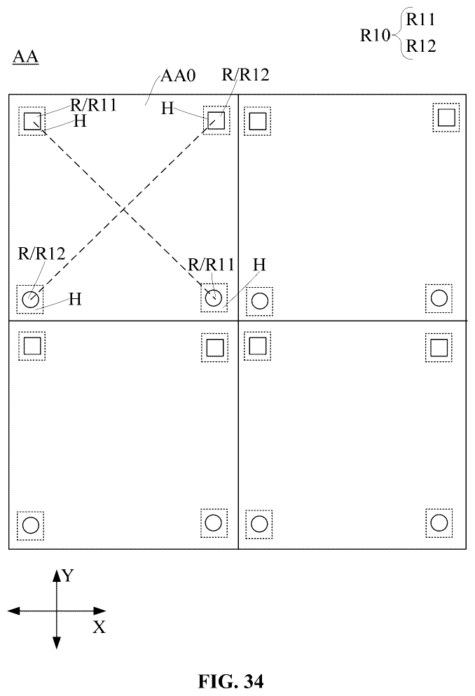

FIG. 33 illustrates another top view of a display panel according to various embodiments of the present disclosure; and FIG. 34 illustrates another top view of a display panel according to various embodiments of the present disclosure. As shown in FIGS. 33-34, when at least two alignment marks R in the sub-display region AA0 include at least two alignment mark groups R10, taking at least two alignment mark groups R10 including the first alignment mark group R11 and the second alignment mark group R12 as an example, the line connecting the geometric centers of two alignment marks R in one of at least two alignment mark groups R10 may intersect the line connecting the geometric centers of two alignment marks R in another one of at least two alignment mark groups R10. For example, the line connecting the geometric centers of two alignment marks R in the first alignment mark group R11 may intersect the lines connecting the geometric centers of two alignment marks R in the second alignment mark group R12. Such configuration may further improve the alignment accuracy of the alignment marks R.

Optionally, as shown in FIG. 33, at least two alignment marks R in the sub-display region AA0 may include two alignment mark groups R10; two alignment mark groups R10 may include the first alignment mark group R11 and the second alignment mark group R12; the line connecting the geometric centers of two alignment marks R in any alignment mark group R10 may pass through the geometric center of the sub-display region AA0; and the line connecting the geometric centers of two alignment marks R in one of two alignment mark groups R10 may be perpendicular to the line connecting the geometric centers of two alignment marks R in another one of two alignment mark groups R10.

Optionally, as shown in FIG. 34, at least two alignment marks R in the sub-display region AA0 may include two alignment mark groups R10; two alignment mark groups R10 may include the first alignment mark group R11 and the second alignment mark group R12; the line connecting the geometric centers of two alignment marks R in any alignment mark group R10 may pass through the geometric center of the sub-display region AA0; and the line connecting the geometric centers of two alignment marks R in one of two alignment mark groups R10 may form a cross with the line connecting the geometric centers of two alignment marks R in another one of two alignment mark groups R10.

As shown in FIGS. 33-34, in the alignment mark groups R10 including the first alignment mark group R11 and the second alignment mark group R12, the shapes of two alignment marks R may be different. For example, one alignment mark R may be rectangular, and another alignment mark R may be circular. In such way, the alignment accuracy of the alignment mark R may not only be improved, and the front and back of the alignment may also be identified during alignment.

In embodiment of the present disclosure, the shape and size of the alignment mark R may be not limited, and the shape and size of the clearance region H may also be not limited. However, in order to clearly identify the alignment mark R, there may be no other graphic boundaries around the alignment mark R that affect the identification of the alignment mark R. As shown in FIG. 7, the minimum distance between the boundary of the alignment mark R and the boundary of the clearance region around the alignment mark R may be configured to be greater than 5 μm, which may ensure desirable identification of the alignment mark R. For example, the alignment mark R may be a rectangle, and the length and width of the alignment mark R may be 30 μm×30 μm. For another example, the alignment mark R may be a circle, and the diameter of the alignment mark R may be 30 μm; and the clearance region H may be a rectangle, and the length and width of the clearance region H may be 40 μm.

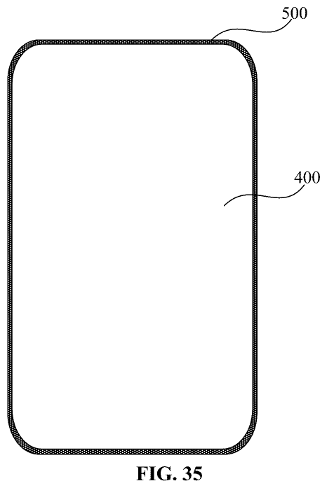

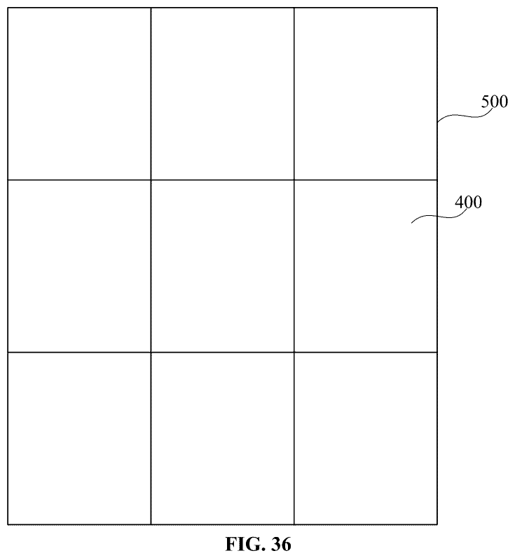

Accordingly, embodiments of the present disclosure further provide a display apparatus. As shown in FIGS. 35-36, a display apparatus 500 may include a display panel 400 provided in any of above-mentioned embodiments. Since the display panel 400 has been described in detail in above-mentioned embodiments, the display panel 400 may not be described in detail herein.

The display apparatus 500 may be any electronic device with display function, such as a touch screen, a mobile phone, a tablet computer, a laptop computer, an e-book, a television or the like.

It should be noted that, since the driving circuit may be configured in the display region in above-mentioned embodiments to realize the design of the display panel with extremely narrow frame or even frameless and full screen, the display apparatus provided in embodiment of the present disclosure may be a spliced display apparatus which may include multiple frameless display units (i.e., the display panel 400).

In the display panel provided in embodiments of the present disclosure, the display region may not only include the plurality of light-emitting elements and the plurality of pixel circuits but also include at least one driving circuit. That is; by configuring at least one driving circuit in the display region, the display panel may be the display panel with an extremely narrow frame or even a frameless frame. Furthermore, by dividing the display region into the plurality of sub-display regions and configuring at least two alignment marks in the sub-display regions, the alignment marks in the sub-display regions may be configured to align the light-emitting elements when being transferred to the array substrate of the display panel. Meanwhile, the alignment mark may be configured in one metal layer of the plurality of metal layers on the side of the active layer away from the base substrate; the clearance region may be configured around the alignment mark; and the plurality of metal layers on the side of the active layer away from the base substrate may expose the alignment mark and the clearance region around the alignment mark, thereby ensuring the alignment mark to be accurately identified. Finally, the light-emitting elements may be accurately transferred to the array substrate of the display panel.

Various parts of the present disclosure may be described in a combination of parallel and progressive manner. Each part may focus on the differences from other parts, and same or similar descriptions between the parts may refer to each other.

With respect to above-mentioned description of disclosed embodiments, the features described in embodiments in the present disclosure may be replaced or combined with each other, such that those skilled in the field may implement or use the present disclosure. Various modifications to above-mentioned embodiments may be apparent to those skilled in the art. The principles defined herein may be implemented in other embodiments without departing from the spirit or scope of the present disclosure. Therefore, the present disclosure may not be limited to embodiments in the present disclosure but may conform to the widest scope consistent with the principles and novel features in the present disclosure.

What is claimed is

1. A display panel, comprising:
a display region, wherein the display region includes a plurality of light-emitting elements, a plurality of pixel circuits and at least one driving circuit; the at least one driving circuit includes multi-level-cascaded shift register circuits; the shift register circuits are configured to transmit a driving signal to the plurality of pixel circuits; and the plurality of pixel circuits is configured to drive the plurality of light-emitting elements; and
an array substrate, wherein the array substrate includes the plurality of pixel circuits and the at least one driving circuit; and the plurality of light-emitting element is on the array substrate, wherein:
the array substrate includes a base substrate, an active layer on a side of the base substrate, and a plurality of metal layers on a side of the active layer away from the base substrate; and
the display region includes a plurality of sub-display regions; a sub-display region includes at least two alignment marks; an alignment mark is configured for alignment when a light-emitting element is transferred to the array substrate; the alignment mark is in a metal layer of the plurality of metal layers; a clearance region is configured around the alignment mark; and the plurality of metal layers exposes the alignment mark and the clearance region around the alignment mark.

2. The display panel according to claim 1, wherein:
along a direction perpendicular to a plane of the base substrate, the alignment mark and the clearance region are not overlapped with the active layer.

3. The display panel according to claim 1, wherein:
the plurality of metal layers includes a first metal layer; the first metal layer includes a physical part and a plurality of openings; the physical part of the first metal layer includes a first power supply structure; and the first power supply structure is configured to provide a first power supply voltage signal;
the plurality of metal layers includes a second metal layer; the second metal layer includes a physical part and a plurality of openings; the physical part of the second metal layer includes a second power supply structure; and the second power supply structure is configured to provide a second power supply voltage signal;
the first power supply structure is electrically connected to a pixel circuit; the pixel circuit is electrically connected to a first electrode of the light-emitting element; and the second power supply structure is electrically connected to a second electrode of the light-emitting element; and
the second metal layer is on a side of the first metal layer away from the base substrate; the alignment mark is in the second metal layer, and an opening of the second metal layer includes the clearance region.

4. The display panel according to claim 3, wherein:
an orthographic projection of the alignment mark and the clearance region around the alignment mark on the first metal layer is in an opening of the first metal layer, or in the physical part of the first metal layer.

5. The display panel according to claim 3, wherein:
an orthographic projection of the clearance region around the alignment mark on the first metal layer is in the physical part of the first metal layer; and
the plurality of openings of the first metal layer includes a first opening; and the first opening is covered by the alignment mark along a direction perpendicular to a plane of the base substrate,

6. The display panel according to claim 5, wherein:
a geometric center of the first opening is coincided with a geometric center of an orthographic projection of the alignment mark on the first metal layer.

7. The display panel according to claim 1, wherein:
the plurality of metal layers includes a first metal layer; the first metal layer includes a physical part and a plurality of openings; the physical part of the first metal layer includes a first power supply structure; and the first power supply structure is configured to provide a first power supply voltage signal;
the plurality of metal layers includes a second metal layer; the second metal layer includes a physical part and a plurality of openings; the physical part of the second metal layer includes a second power supply structure; and the second power supply structure is configured to provide a second power supply voltage signal;
the first power supply structure is electrically connected to a pixel circuit; the pixel circuit is electrically connected to a first electrode of the light-emitting element; and the second power supply structure is electrically connected to a second electrode of the light-emitting element;
the second metal layer is on a side of the first metal layer away from the base substrate, the alignment mark is in the first metal layer, and an opening of the first metal layer includes the clearance region; and
along a direction perpendicular to a plane of the base substrate, an opening of the second metal layer exposes the alignment mark and the clearance region around the alignment mark.

8. The display panel according to claim 1, wherein:
the plurality of metal layers includes a first metal layer; the first metal layer includes a physical part and a plurality of openings; the physical part of the first metal layer includes a first power supply structure; and the first power supply structure is configured to provide a first power supply voltage signal;
the plurality of metal layers includes a second metal layer; the second metal layer is on a side of the first metal layer away from the base substrate; the second metal layer includes a physical part and a plurality of openings; the physical part of the second metal layer includes a second power supply structure; and the second power supply structure is configured to provide a second power supply voltage signal;
the first power supply structure is electrically connected to a pixel circuit; the pixel circuit is electrically connected to a first electrode of the light-emitting element; and the second power supply structure is electrically connected to a second electrode of the light-emitting element;
the plurality of metal layers further includes a third metal layer; and the third metal layer is on a side of the first metal layer facing toward the base substrate and includes a physical part and a plurality of openings; and
the alignment mark is in the third metal layer; an opening of the third metal layer includes the clearance region; and along a direction perpendicular to a plane of the base substrate, an opening of the first metal layer and an opening of the second metal layer expose the alignment mark and the clearance region around the alignment mark.

9. The display panel according to claim 3, wherein:
the display panel includes pixel circuit groups; a pixel circuit group includes at least two pixel circuits; the pixel circuit groups are arranged in a row along a first direction; multiple rows of the pixel circuit groups are arranged along a second direction; the first direction intersects the second direction; and the first direction and the second direction are in parallel with a plane of the base substrate;
along a direction perpendicular to the plane of the base substrate, the first power supply structure is at least partially overlapped with four pixel circuit groups that two adjacent rows of pixel circuit groups are overlapped with two adjacent columns of pixel circuit groups;
along the direction perpendicular to the plane of the base substrate, the second power supply structure is at least partially overlapped with four pixel circuit groups that two adjacent rows of pixel circuit groups are overlapped with two adjacent columns of pixel circuit groups; and
the active layer includes a first active portion; the pixel circuit includes the first active portion; and along the direction perpendicular to the plane of the base substrate, at least one of the physical part of the first metal layer and the physical part of the second metal layer covers the first active portion.

10. The display panel according to claim 9, wherein:
the pixel circuit includes a pulse width module and an amplitude module, and the first power supply structure is electrically connected to the amplitude module of the pixel circuit.

11. The display panel according to claim 9, wherein:
the display panel includes light-emitting element groups, a light-emitting element group includes at least two light-emitting elements, and one pixel circuit group is electrically connected to one light-emitting element group;
the display region includes a first display region and a second display region; and the second display region at least partially surrounds the first display region;
the second display region includes a plurality of light-emitting element groups, a plurality of pixel circuit groups and the at least one driving circuit; and in the second display region, along the direction perpendicular to the plane of the base substrate, a pixel circuit group is at least not partially overlapped with a light-emitting element group electrically connected to the pixel circuit group; and
the first display region includes a plurality of light-emitting element groups and a plurality of pixel circuit groups; and in the first display region, along the direction perpendicular to the plane of the base substrate, a pixel circuit group is at least not partially overlapped with a light-emitting element group electrically connected to the pixel circuit group.

12. The display panel according to claim 11, wherein:
in the second display region, the plurality of openings of the second metal layer includes a plurality of second openings;
in the first display region, the plurality of openings of the second metal layer includes a plurality of second openings and a plurality of third openings; and an area of a third opening is greater than an area of a second opening;
in the first display region, the pixel circuit group is configured with a wiring region on at least one side along the first direction, the wiring region includes a signal line extending along the second direction, the third opening is in the wiring region, and the plurality of third openings is arranged along the second direction in the wiring region; and
the sub-display region is at least partially overlapped with the first display region; and the alignment mark and the clearance region around the alignment mark are in the third opening.

13. The display panel according to claim 11, wherein:
in the second display region, the plurality of openings of the first metal layer includes a plurality of fourth openings;
in the first display region, the plurality of openings of the first metal layer includes a plurality of fourth openings and a plurality of fifth openings; and an area of a fifth opening is greater than an area of a fourth opening;
in the first display region, the pixel circuit group is configured with a wiring region on at least one side along the first direction, the wiring region includes a signal line extending along the second direction, the fifth opening is in the wiring region, and the plurality of fifth openings is arranged along the second direction in the wiring region; and
the sub-display region is at least partially overlapped with the first display region; and the alignment mark and the clearance region around the alignment mark are at the fifth opening.

14. The display panel according to claim 11, wherein:
in the second display region, the plurality of openings of the second metal layer includes a plurality of second openings;
in the first display region, the plurality of openings of the second metal layer includes a plurality of second openings and a plurality of third openings; and an area of a third opening is greater than an area of a second opening;
in the first display region, the pixel circuit group is configured with a wiring region on at least one side along the first direction, the wiring region includes a signal line extending along the second direction, the third opening is in the wiring region, and the plurality of third openings is arranged along the second direction in the wiring region;
in the second display region, the plurality of openings of the first metal layer includes a plurality of fourth openings;
in the first display region, the plurality of openings of the first metal layer includes a plurality of fourth openings and a plurality of fifth openings; and an area of a fifth openings is greater than an area of a fourth openings;
in the first display region, the fifth opening is in the wiring region, and the plurality of fifth openings is arranged along the second direction in the wiring region;
orthographic projections of the plurality of third openings on the first metal layer and the plurality of fifth openings are arranged alternately along the second direction; and
the sub-display region is at least partially overlapped with the first display region; and the alignment mark and the clearance region around the alignment mark are at the third opening or at the fifth opening.

15. The display panel according to claim 14, wherein:
in the first display region, along the second direction, the plurality of third openings and the plurality of second openings are arranged alternately;
in the first display region, along the second direction, the plurality of fifth openings and the plurality of fourth openings are arranged alternately; and
orthographic projections of the plurality of third openings on the first metal layer are overlapped with the plurality of fourth openings between two adjacent fifth openings; and/or orthographic projections of the plurality of fifth openings on the second metal layer are overlapped with the plurality of second openings between two adjacent third openings.

16. The display panel according to claim 1, wherein:
the display panel includes pixel circuit groups; a pixel circuit group includes at least two pixel circuits; the pixel circuit groups are arranged in a row along a first direction; multiple rows of the pixel circuit groups are arranged along a second direction; the first direction intersects the second direction; and the first direction and the second direction are in parallel with a plane of the base substrate;
in the sub-display region, the at least two alignment marks include at least one alignment mark group; and an alignment mark group includes two alignment marks;
when the at least two alignment marks include one alignment mark group, a line connecting geometric centers of the two alignment marks in one alignment mark group intersects both the first direction and the second direction; and
when the at least two alignment marks include at least two alignment mark groups, a line connecting geometric centers of two alignment marks in one of the at least two alignment mark groups intersects a line connecting geometric centers of two alignment marks in another one of the at least two alignment mark groups.

17. The display panel according to claim 16, wherein:
in the sub-display region, the at least two alignment marks include one alignment mark group; and a line connecting geometric centers of two alignment marks in one alignment mark group is coincided with a diagonal line of the sub-display region.

18. The display panel according to claim 16, wherein:
in the sub-display region, the at least two alignment marks include two alignment mark groups; and
a line connecting geometric centers of two alignment marks in any alignment mark group passes through a geometric center of the sub-display region; and a line connecting geometric centers of two alignment marks in one of the two alignment mark groups is perpendicular to or crosses a line connecting geometric centers of two alignment marks in another one of the two alignment mark groups.

19. The display panel according to claim 16, wherein:
shapes of the two alignment marks in the alignment mark group are different.

20. A display apparatus, comprising:
a display panel, comprising:
a display region, wherein the display region includes a plurality of light-emitting elements, a plurality of pixel circuits and at least one driving circuit; the at least one driving circuit includes multi-level-cascaded shift register circuits; the shift register circuits are configured to transmit a driving signal to the plurality of pixel circuits; and the plurality of pixel circuits is configured to drive the plurality of light-emitting elements; and
an array substrate, wherein the array substrate includes the plurality of pixel circuits and the at least one driving circuit; and the plurality of light-emitting element is on the array substrate, wherein:
the array substrate includes a base substrate, an active layer on a side of the base substrate, and a plurality of metal layers on a side of the active layer away from the base substrate; and
the display region includes a plurality of sub-display regions; a sub-display region includes at least two alignment marks; an alignment mark is configured for alignment when a light-emitting element is transferred to the array substrate; the alignment mark is in a metal layer of the plurality of metal layers; a clearance region is configured around the alignment mark; and the plurality of metal layers exposes the alignment mark and the clearance region around the alignment mark.
